(19) United States
(12) Patent Application Publication
(10) Pub. No.: US 2015/0340610 A1
(43) Pub. Date: Nov. 26, 2015

(54) VARIABLE RESISTANCE MEMORY DEVICES AND METHODS OF MANUFACTURING THE SAME

(71) Applicant: SAMSUNG ELECTRONICS CO., LTD., SUWON-SI (KR)

(72) Inventors: SEUNG-JAE JUNG, SUWON-SI (KR); YOUN-SEON KANG, YONGIN-SI (KR)

(21) Appl. No.: 14/607,121

(22) Filed: Jan. 28, 2015

(30) Foreign Application Priority Data
May 26, 2014 (KR) 10-2014-0062767

(51) Int. Cl. H01L 45/00; H01L 27/24

(52) U.S. Cl. CPC H01L 45/1293; H01L 45/1233; H01L 45/145; H01L 45/14; H01L 27/2463; H01L 45/16

(57) ABSTRACT

A variable resistance memory device includes first conductive lines extending in a first direction, second conductive lines over the first conductive lines, which extend in a second direction not parallel to the first direction, memory cells including a variable resistance element, each of which is formed at an intersection of the first and second conductive lines, first insulation layer patterns extending in the first direction between the memory cells, second insulation layer patterns extending in the second direction between the memory cells, first thermal barrier layer patterns extending in the first direction, which is spaced apart from the memory cells in the second direction between the first insulation layer patterns, and second thermal barrier layer patterns extending in the second direction, which is spaced apart from the memory cells in the first direction between the second insulation layer patterns.

### PRIORITY STATEMENT

This application claims priority under 35 USC §119 to Korean Patent Application No. 10-2014-0062767, filed on May 26, 2014 in the Korean Intellectual Property Office (KIPO), the contents of which are hereby incorporated by reference in their entirety.

### BACKGROUND

1. Field

The inventive concepts relate to variable resistance memory devices and methods of manufacturing the same. More In particular, the inventive concepts relate to variable resistance memory devices having cross point array structures and methods of manufacturing the same.

2. Description of the Related Art

Recently, memory devices having a variable resistance property have been developed. Examples of the memory devices include a resistive random access memory (ReRAM) device, a phase change random access memory (PRAM) device, and a magnetic random access memory (MRAM) device.

In the memory devices, a memory cell including a variable resistance layer may be disposed between upper and lower electrodes or between upper and lower conductive lines. As an integration degree of a memory device increases, a distance or a pitch between neighboring memory cells may decrease so that a thermal interference and/or an electrical interference between the memory cells may occur, and thus an operational reliability of the memory device may be deteriorated.

### SUMMARY

There is provided a variable resistance memory device, according to an aspect of the inventive concepts, which includes a plurality of first conductive lines extending in a first direction, a plurality of second conductive lines disposed over the first conductive lines and extending in a second direction that is not parallel to the first direction, a plurality of memory cells each including a variable resistance element and disposed at locations at which the first and second conductive lines overlap each other, respectively, a plurality of first insulation layer patterns extending in the first direction between the memory cells; a plurality of second insulation layer patterns extending in the second direction between the memory cells a plurality of first thermal barrier layer patterns extending in the first direction between the first insulation layer patterns and which are separated from the memory cells in the second direction by the first insulation layer patterns, and a plurality of second thermal barrier layer patterns extending in the second direction between the second insulation layer patterns and which are separated from the memory cells in the first direction by the second insulation layer patterns.

There is also provided, according to another aspect of the inventive concepts, a cross point memory cell array which includes a base, memory cells disposed on the base and arrayed in first and second directions, first conductive lines extending parallel to each other in the first direction and interposed between the memory cells and the base second conductive lines disposed on the array of memory cells, the second conductive lines extending parallel to each other in the second direction, and a barrier separating the memory cells from one another, and in which the barrier comprises an insulation layer pattern structure extending along sidewall surfaces of the memory cells, and a thermal barrier layer pattern structure interposed between adjacent ones of the memory cells in the first and second directions, the thermal conductivity of the thermal barrier layer pattern structure being lower than that of the insulation layer pattern structure.

There is also provided, according to another aspect of the inventive concepts, a method of manufacturing a variable resistance memory device, which includes forming a first conductive layer and a first variable resistance material layer on a base insulation layer, etching the first variable resistance material layer and the first conductive layer to form a plurality of first trenches extending in a first direction, forming a first insulation layer pattern along sides of each of the first trenches and then forming a first thermal barrier layer pattern over the first insulation layer pattern in the first trenches, forming a second conductive layer on the first variable resistance material layer, the first insulation layer pattern and the first thermal barrier layer pattern, etching the first conductive layer, the first variable resistance material layer and the second conductive layer to form a plurality of second trenches extending in a second direction not parallel to the first direction, and forming a second insulation layer pattern along sides of each of the second trenches and thereafter forming a second thermal barrier layer pattern over the second insulation layer pattern in the second trenches.

### BRIEF DESCRIPTION OF THE DRAWINGS

The inventive concepts will be more clearly understood from the following detailed description taken in conjunction with the accompanying drawings. FIGS. 1 to 49 illustrate non-limiting embodiments according to the inventive concepts.

FIGS. 1, 2, 3A and 3B are a perspective view, a top view, and cross-sectional views, respectively, illustrating a variable resistance memory device in accordance with the inventive concepts;

FIGS. 4-13 illustrate stages of a method of manufacturing a variable resistance memory device in accordance with the inventive concepts, with FIGS. 4, 5A, 6, 7, 8 and 9A being cross-sectional views along the second direction in FIG. 1, FIGS. 9B, 10A, 11, 12 and 13 being cross-sectional views taken along the first direction, and FIGS. 5B and 10B being top views of the device during the stages shown in FIGS. 5A and 10A, respectively;

FIG. 14 is a perspective view of another embodiment of a variable resistance memory device in accordance with the inventive concepts, and FIGS. 15A and 15B are cross-sectional views of the variable resistance memory device taken along the second direction and the first direction in FIG. 14, respectively;

FIGS. 16-21 illustrate stages of a method of manufacturing a variable resistance memory device in accordance with the inventive concepts, with FIGS. 16, 17 and 18 being cross-sectional views of the variable resistance memory device taken along a direction corresponding to the second direction in FIG. 14, and FIGS. 19, 20 and 21 being cross-sectional views of the variable resistance memory device taken along the first direction;

FIGS. 22A and 22B are cross-sectional views, taken along first and second directions, respectively, illustrating another embodiment of a variable resistance memory device in accordance with the inventive concepts;

FIGS. 23-27 illustrate stages of another embodiment of a method of manufacturing a variable resistance memory device in accordance with the inventive concepts, with FIGS. 23, 24 and 25 being cross-sectional views of the variable resistance memory device along second direction, and FIGS. 26 and 27 being cross-sectional views of the variable resistance memory device along a first direction;

FIGS. 28A and 28B are cross-sectional views illustrating a stacked variable resistance memory device in accordance with the inventive concepts taken along first and second directions, respectively;

FIGS. 29A and 29B are cross-sectional views illustrating a stacked variable resistance memory device in accordance with the inventive concepts taken along first and second directions, respectively;

FIGS. 30A and 30B are cross-sectional views illustrating a stacked variable resistance memory device in accordance with the inventive concepts;

FIGS. 31-37 illustrate stages of a method of manufacturing a stacked variable resistance memory device in accordance with the inventive concepts, with each of FIGS. 31, 32, 33A, 36A and 37 being a cross-sectional views along a second direction and each of FIGS. 33B, 34, 35 and 36B being a cross-sectional view along a first direction;

FIGS. 38A and 38B are cross-sectional views illustrating a stacked variable resistance memory device in accordance with the inventive concepts;

FIGS. 39-43 illustrate stages of a method of manufacturing a stacked variable resistance memory device in accordance with the inventive concepts, with FIGS. 39, 40, 41A, 43 and 44 each being a cross-sectional view cut along the second direction and FIGS. 41B and 42 each being a cross-sectional view along the first direction;

FIG. 44 is a cross-sectional view illustrating a semiconductor device in accordance with the inventive concepts;

FIGS. 45, 46, 47 and 48 are cross-sectional views illustrating stages of a method of manufacturing a semiconductor device in accordance with the inventive concepts; and

FIG. 49 is a block diagram illustrating an information processing system in accordance with the inventive concepts.

### DETAILED DESCRIPTION OF THE PREFERRED EMBODIMENTS

Various the inventive concepts will be described more fully hereinafter with reference to the accompanying drawings, in which some the inventive concepts are shown. The present inventive concept may, however, be embodied in many different forms and should not be construed as limited to the inventive concepts set forth herein. Rather, these the inventive concepts are provided so that this description will be thorough and complete, and will fully convey the scope of the present inventive concept to those skilled in the art. In the drawings, the sizes and relative sizes of layers and regions may be exaggerated for clarity. Like reference numerals designate like elements throughout the drawings.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. The term “extending” will generally refer to the longest dimension of an element or feature in a Cartesian system as illustrated in the drawings, e.g., the lengthwise direction of line element, even when not explicitly stated as the context of the description and figures will make clear.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another region, layer or section and not, for example, any particular order in which they are formed.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

The terminology used herein is for the purpose of describing particular the inventive concepts only and is not intended to be limiting of the present inventive concept. For example, it will be understood that the terms “comprises” and “comprising” when used in this specification, specify the presence of stated features, integers, steps, operations, elements, and/or components, but do not preclude the presence or addition of one or more other features, integers, steps, operations, elements, components, and/or groups thereof.

The inventive concepts are described herein with reference to cross-sectional illustrations that are schematic illustrations of idealized the inventive concepts (and intermediate structures). As such, variations from the shapes of the illustrations as a result, for example, of manufacturing techniques and/or tolerances, are to be expected. Thus, the inventive concepts should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Embodiments of memory devices and methods of manufacturing the same will now be described with reference to the figures.

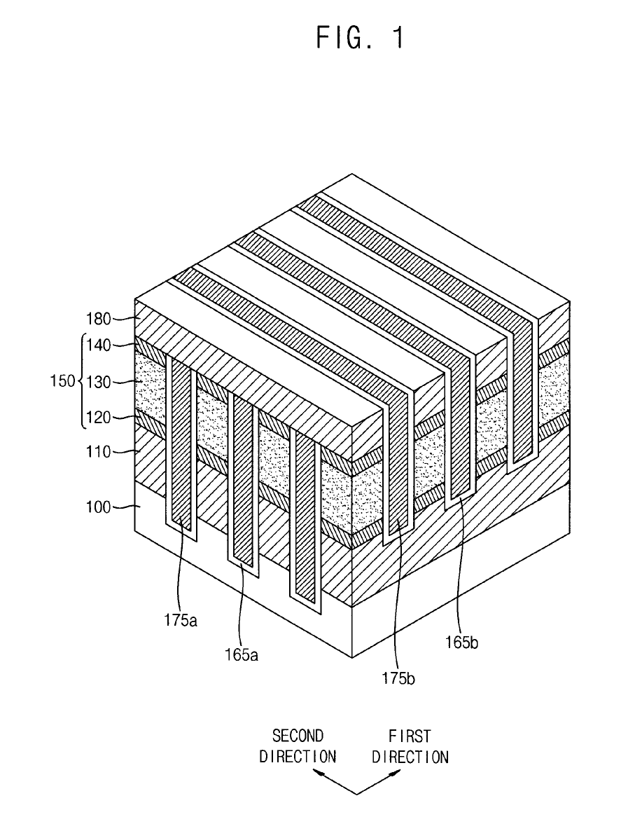

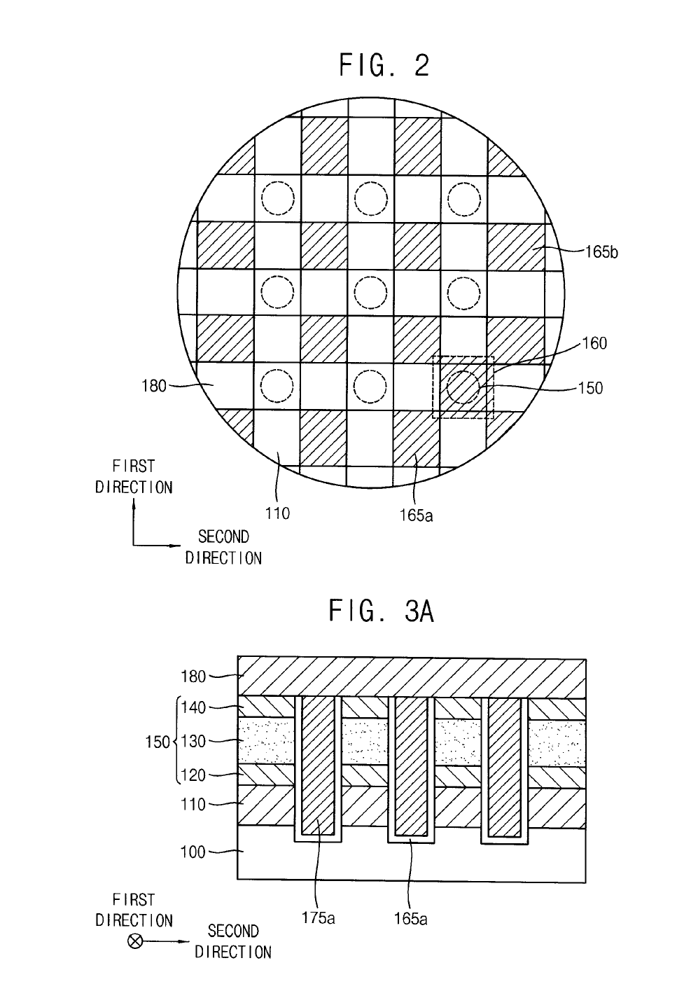

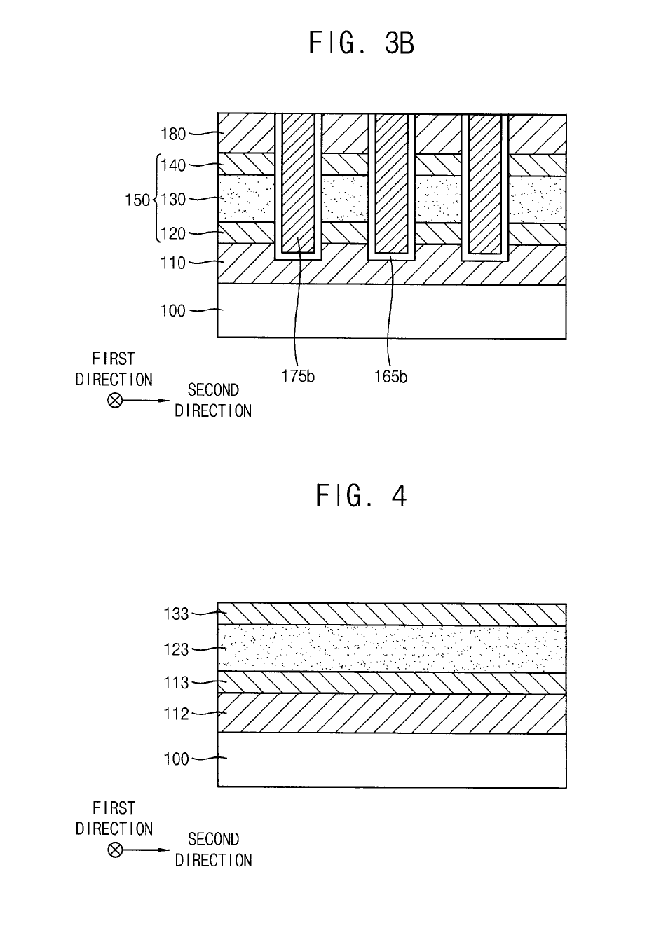

FIGS. 1, 2, 3A and 3B are a perspective view, a top view, and cross-sectional views, respectively, illustrating a variable resistance memory device in accordance with the inventive concepts. In particular, FIG. 1 is a perspective view of the variable resistance memory device, and FIG. 2 is a top view of the variable resistance memory device. FIGS. 3A and 3B are cross-sectional views of the variable resistance memory device.

FIGS. 1, 2, 3A and 3B illustrate a variable resistance device having a cross-point memory cell array structure in which one variable resistance element is formed at each intersection at which conductive lines cross each other. For convenience of explanation, FIGS. 1 and 2 illustrate only a first conductive line, a second conductive line, a memory cell and a thermal barrier layer pattern structure, and other insulation structures are not shown therein.

Referring to FIGS. 1, 2, 3A and 3B, the variable resistance memory device may include a first conductive line 110, a second conductive line 180, a memory cell 150 and a thermal barrier layer pattern structure on a base insulation layer 100.

In this embodiment according to the inventive concepts, a plurality of first conductive lines 110 and a plurality of second conductive lines 180 may be formed. The memory cell 150 may be formed at an intersection 160 at which the first and second conductive lines 110 and 180 cross each other.

The base insulation layer 100 may include an insulating material, e.g., silicon oxide, silicon nitride, silicon oxynitride or the like. The base insulation layer 100 may cover lower structures (not shown), e.g., transistors, formed on a substrate (not shown).

The first conductive line 110 may extend in a first direction that is parallel to a top surface of the base insulation layer 100. In an embodiment according to the inventive concepts, a plurality of first conductive lines 110 may be arranged in a second direction that is parallel to the top surface of the base insulation layer 100 and is not parallel to the first direction.

In an embodiment according to the inventive concepts, the first and second directions may be substantially perpendicular to each other. Alternatively, the first and second directions may form an acute angle with each other. The definition of the first and second directions may be the same throughout all specifications.

The first conductive line 110 may include a metal, e.g., tungsten (W), copper (Cu), aluminum (Al), titanium (Ti), tantalum (Ta) or the like. In an embodiment according to the inventive concepts, the first conductive line 110 may serve as a bit line or a word line.

The second conductive line 180 may extend in the second direction. In an embodiment according to the inventive concepts, a plurality of the second conductive lines 180 may be arranged in the first direction.

The second conductive line 180 may include a metal, e.g., tungsten (W), copper (Cu), aluminum (Al), titanium (Ti), tantalum (Ta) or the like. In an embodiment according to the inventive concepts, the second conductive line 180 may serve as a word line when the first conductive line 110 serves as a bit line. Alternatively, the second conductive line 180 may serve as a bit line when the first conductive line 110 serves as a word line.

As the plurality of first conductive lines 110 and the plurality of second conductive lines 180 are formed, a plurality of memory cells may be formed at the intersection 160 at which the first and second conductive lines 110 and 180 overlap or cross each other. The plurality of memory cells 150 may be arranged in the first direction to form a memory cell column. The plurality of memory cells 150 may be arranged in the second direction to form a memory cell row.

The memory cell 150 may include a variable resistance layer 130.

In an embodiment according to the inventive concepts, the variable resistance layer 130 may include a material of which a resistance may be changed by an oxygen vacancy or an oxygen migration. In this case, the variable resistance memory device may be a ReRAM device.

For example, the variable resistance layer 130 may include a perovskite-based material or a transition metal oxide. The perovskite-based material may include, e.g., STO (SrTiO₃), BTO (BaTiO₃), PCMO (Pr_{1-X}Ca_{X}MnO₃) or the like. The transition metal oxide may include titanium oxide (TiOx), zirconium oxide (ZrOx), aluminum oxide (AlOx), hafnium oxide (HfOx), tantalum oxide (TaOx), niobium oxide (NbOx), cobalt oxide (CoOx), tungsten oxide (WOx), lanthanum oxide (LaOx) or zinc oxide (ZnOx). These may be used alone or in combination.

The variable resistance layer 130 may have a multi-layered structure including the above-mentioned materials. For example, the variable resistance layer 130 may include a first hafnium oxide (HfO₂) layer, a second hafnium oxide (HfOx) layer and a zirconium oxide layer sequentially stacked. Alternatively, the variable resistance layer 130 may include a titanium aluminum oxide (TiAlOx) layer, a tantalum oxide layer and an aluminum oxide layer sequentially stacked.

In an example of the present embodiment, the variable resistance memory device may be a PRAM device, and thus the variable resistance layer 130 may include a material whose resistance may be changed by a phase change or a phase transition. In this case, the variable resistance layer 130 may include a chalcogenide-based material in which germanium (Ge), antimony (Sb) and/or tellurium (Te) are combined in a given ratio.

In another example of the present embodiment, the variable resistance memory device may be an MRAM device, and thus the variable resistance layer 130 may include a material whose resistance may be changed by a magnetic field or a spin transfer torque (STT). In this case, the variable resistance layer 130 may include a ferromagnetic material, e.g., iron (Fe), nickel (Ni), cobalt (Co), dysprosium (Dy), gadolinium (Gd) or the like.

In an embodiment according to the inventive concepts, the memory cell 150 may Furthermore include a lower electrode 120 interposed between the first conductive line 110 and the variable resistance layer 130, and an upper electrode 140 interposed between the second conductive line 180 and the variable resistance layer 130.

The lower electrode 120 and the upper electrode 140 may include a metal nitride or a metal silicon nitride, e.g., titanium nitride (TiNx), titanium silicon nitride (TiSiNx), tungsten nitride (WNx), tungsten silicon nitride (WSiNx), tantalum nitride (TaNx), tantalum silicon nitride (TaSiNx), zirconium nitride (ZrNx), zirconium silicon nitride (ZrSiNx) or the like.

The thermal barrier layer pattern structure may be formed between the memory cells 150. In an embodiment according to the inventive concepts, the thermal barrier layer pattern structure may include a first thermal barrier layer pattern 175a and a second thermal barrier layer pattern 175b.

The first thermal barrier layer pattern 175a may be formed between neighboring memory cell columns, and may extend in the first direction. As shown in FIG. 3A, the first conductive lines 110 may be separated or insulated from each other by the first thermal barrier layer pattern 175a. In an example of the present embodiment, the first thermal barrier layer pattern 175a may extend through an upper portion of the base insulation layer 100 so that a lower portion of the first thermal barrier layer pattern 175a may be surrounded by the base insulation layer 100.

The second thermal barrier layer pattern 175b may be formed between neighboring memory cell rows, and may extend in the second direction. As shown in FIG. 3B, the second conductive lines 180 may be separated or insulated from each other by the second thermal barrier layer pattern 175b. In an example of the present embodiment, the second thermal barrier layer pattern 175b may extend through an upper portion of the first conductive line 110 so that a lower portion of the second thermal barrier layer pattern 175b may be surrounded by the first conductive line 110.

As shown in FIGS. 3A and 3B, an insulation layer pattern structure may be formed on a sidewall of the memory cell 150. In an embodiment according to the inventive concepts, the insulation layer pattern structure may include a first insulation layer pattern 165a covering the first thermal barrier layer pattern 175a and a second insulation layer pattern 165b covering the second thermal barrier layer pattern 175b. The insulation layer pattern structure comprises an insulating material, e.g., silicon oxide, silicon nitride or the like.

The first and second insulation layer patterns 165a and 165b may cover sidewalls and bottom surfaces of the first and second thermal barrier layer patterns 175a and 175b, respectively. Thus, the first insulation layer pattern 165a may be formed on the sidewall of the memory cell 150 and a sidewall of the first conductive line 110. The second insulation layer pattern 165b may be formed on the sidewall of the memory cell 150 and a sidewall of the second conductive line 180. The first and second thermal barrier layer patterns 175a and 175b may be separated by the first and second insulation layer patterns 165a and 165b, respectively, from the memory cells 150 adjacent thereto.

In an embodiment according to the inventive concepts, each of the first and second thermal barrier layer patterns 175a and 175b includes a material having a thermal conductivity lower than those of the first and second insulation layer patterns 165a and 165b. In an example of the present embodiment, the first and second insulation layer patterns 165a and 165b are layers of silicon oxide and thus, each of the first and second thermal barrier layer patterns 175a and 175b are of material having a thermal conductivity lower than silicon oxide. Each of the first and second thermal barrier layer patterns 175a and 175b may be of material having a thermal conductivity lower than 1 W/m·K, e.g., GST, porous silicon oxide, polyimide, tungsten selenium (WSe₂) or the like. These may be used alone or in combination.

In an embodiment according to the inventive concepts, the variable resistance memory device may include the first and second insulation layer patterns 165a and 165b crossing each other between the memory cells 150, and the first and second thermal barrier layer patterns 175a and 175b being covered by the first and second insulation layer patterns 165a and 165b, respectively. Thus, each memory cell 150 may be surrounded by the first insulation layer pattern 165a and the first thermal barrier layer pattern 175a sequentially stacked, and by the second insulation layer pattern 165b and the second thermal barrier layer pattern 175b sequentially stacked. Accordingly, a cross-talk, a parasitic capacitance or an interference generated between neighboring memory cells 150 may be minimized

When a voltage is applied to the variable resistance memory device, heat may be generated from the memory cell 150, which may be transferred to neighboring memory cells 150, and thus the variable resistance memory device may be deteriorated. In an embodiment according to the inventive concepts, however, the memory cells 150 of the variable resistance memory device are surrounded by the first and second thermal barrier layer patterns 175a and 175b including materials having thermal conductivities lower than those of the first and second insulation layer patterns 165a and 165b, respectively, and heat transfer between the memory cells 150 may be decreased so that an operational reliability of the variable resistance memory device may be improved.

FIGS. 4 to 13 illustrate stages of a method of manufacturing a variable resistance memory device in accordance with the inventive concepts.

Referring to FIG. 4, a first conductive layer 112, a lower electrode layer 113, a variable resistance material layer 123 and an upper electrode layer 133 may be sequentially formed on a base insulation layer 100.

The base insulation layer 100 may include an insulating material, e.g., silicon oxide, silicon nitride or silicon oxynitride. The base insulation layer 100 may cover lower structures (not shown), e.g., transistors, formed on a substrate (not shown).

The first conductive layer 112 may be formed of metal, e.g., tungsten (W), copper (Cu), aluminum (Al), titanium (Ti), tantalum (Ta) or the like. These may be used alone or in combination.

The lower electrode layer 113 and the upper electrode layer 133 may be formed of at least one material selected from the group consisting of metal nitrides and metal silicon nitrides. For example, the lower and upper electrode layers 113 and 133 may be formed of titanium nitride, titanium silicon nitride, tungsten nitride, tungsten silicon nitride, tantalum nitride, tantalum silicon nitride, zirconium nitride, zirconium silicon nitride or the like. These may be used alone or in combination.

The material for forming the variable resistance material layer 123 may be selected in consideration of the type of the variable resistance memory device to be manufactured. In an embodiment according to the inventive concepts, the variable resistance memory device is a ReRAM device. Therefore, the variable resistance material layer 123 may be formed using a perovskite-based material or a transition metal oxide. For example, the variable resistance material layer 123 may be formed of STO, BTO, PCMO, titanium oxide, zirconium oxide, aluminum oxide, hafnium oxide, tantalum oxide, niobium oxide, cobalt oxide, tungsten oxide, lanthanum oxide, zinc oxide or the like. These may be used alone or in combination. The variable resistance material layer 123 may be formed to have a multi-layered structure including several of the above materials.

In another example of the present embodiment according to the inventive concepts, the variable resistance memory device is a PRAM device. Therefore, the variable resistance material layer 123 may be formed using a chalcogenide-based material. In still another example of the present embodiment, the variable resistance memory device is an MRAM device. Therefore, the variable resistance material layer 123 may be formed of ferromagnetic material, e.g., iron (Fe), nickel (Ni), cobalt (Co), dysprosium (Dy), gadolinium (Gd) or the like.

The first conductive layer 112, the lower electrode layer 113, the variable resistance material layer 123 and the upper electrode layer 133 may be formed by a physical vapor deposition (PVD) process, a sputtering process, an atomic layer deposition (ALD) process or a chemical vapor deposition (CVD) process.

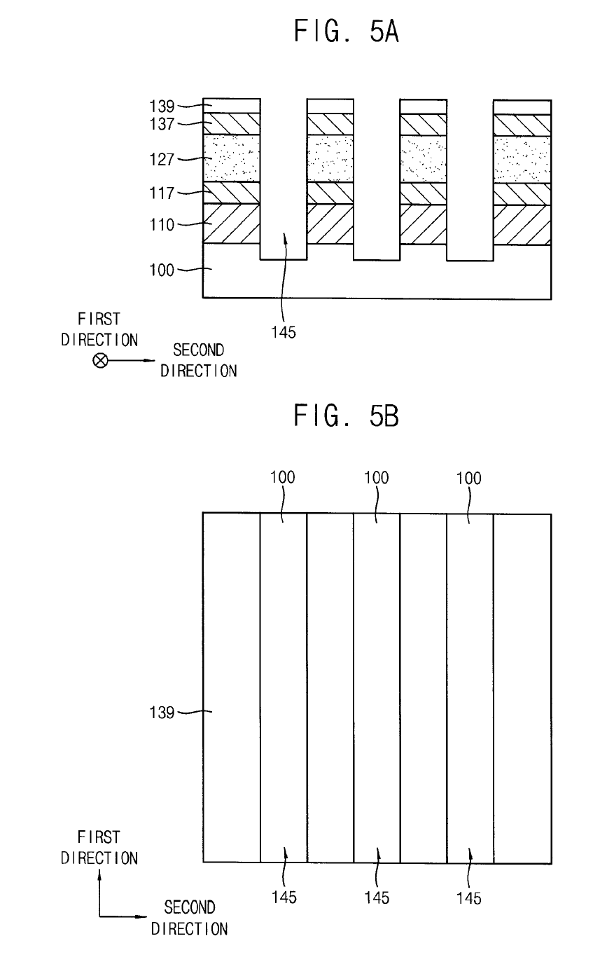

Referring to FIGS. 5A and 5B, a first trench 145 may be formed through the upper electrode layer 133, the variable resistance material layer 123, the lower electrode layer 113, and the first conductive layer 112 to expose an upper portion of the base insulation layer 100.

In an embodiment according to the inventive concepts, a first mask 139 extending in the first direction may be formed on the upper electrode layer 133 so that the first mask 139 may partially expose a top surface of the upper electrode layer 133. The first trench 145 may be formed through the upper electrode layer 133, the variable resistance material layer 123, the lower electrode layer 113 and the first conductive layer 112 by a dry etching process using the first mask 139 as an etching mask. The first mask 139 may be formed of a photoresist material or polysilicon.

An upper portion of the base insulation layer 100 may be also etched when the first trench 145 is formed by the etching process.

In an embodiment according to the inventive concepts, the first trench 145 may extend in the first direction, and a plurality of first trenches 145 may be formed in the second direction. By the formation of the first trench 145, a first conductive line 110, a lower electrode layer pattern 117, a variable resistance material layer pattern 127 and an upper electrode layer pattern 137, which may be sequentially stacked on the base insulation layer 100 and extend in the first direction, may be formed.

As described above, the first trench 145 may be formed through the base insulation layer 100. Thus, a plurality of first conductive lines 110 separated from each other may be formed. For example, when the first conductive layer 112 is etched, an etching residue may remain on a top surface of the base insulation layer 100 to cause interference between neighboring first conductive lines 110. In an embodiment according to the inventive concepts, however, the base insulation layer 100 may be over-etched during the formation of the first trench 145 so that the etching residue may be also removed. Therefore, a reliability of a signal transfer through the first conductive line 110 may be improved.

In an embodiment according to the inventive concepts, the first conductive line 110 may serve as a word line or a bit line of the variable resistance memory device.

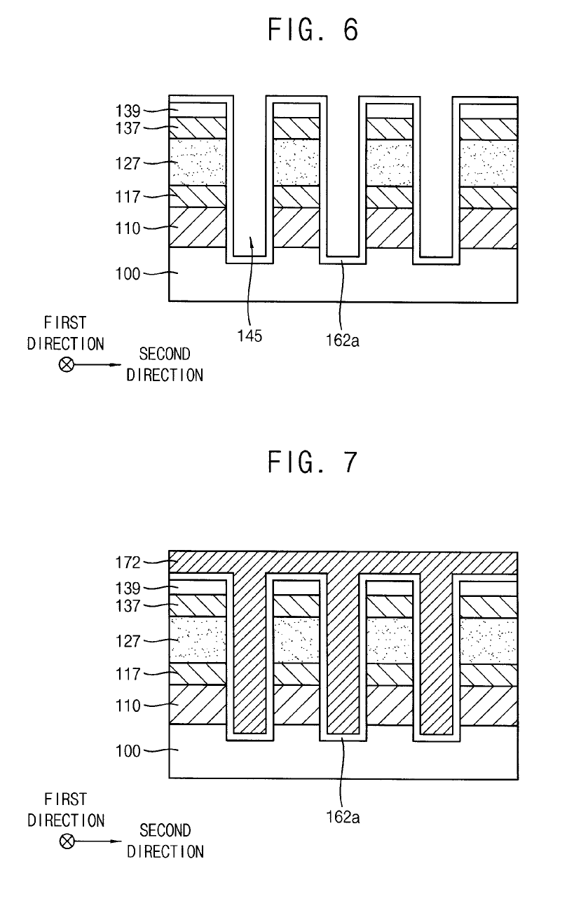

Referring to FIG. 6, a first insulation layer 162a may be formed on the first mask 139a and a sidewall and a bottom surface of the first trench 145.

The first insulation layer 162a may be formed of insulating material, e.g., silicon nitride, silicon oxide or the like, by a CVD process or an ALD process.

Referring to FIG. 7, a first thermal barrier layer 172 may be formed on the first insulation layer 162a.

The first thermal barrier layer 172 may be formed to sufficiently fill the first trench 145 by a CVD process or an ALD process.

In an embodiment according to the inventive concepts, the first thermal barrier layer 172 is formed of material having a thermal conductivity lower than that of the first insulation layer 162a. In an example of the present embodiment, the first thermal barrier layer 172 is formed of material having a thermal conductivity lower than silicon oxide, e.g., at least one of GST, porous silicon oxide, polyimide, and tungsten selenium (WSe₂), and the first insulation layer 162 is formed of silicon oxide.

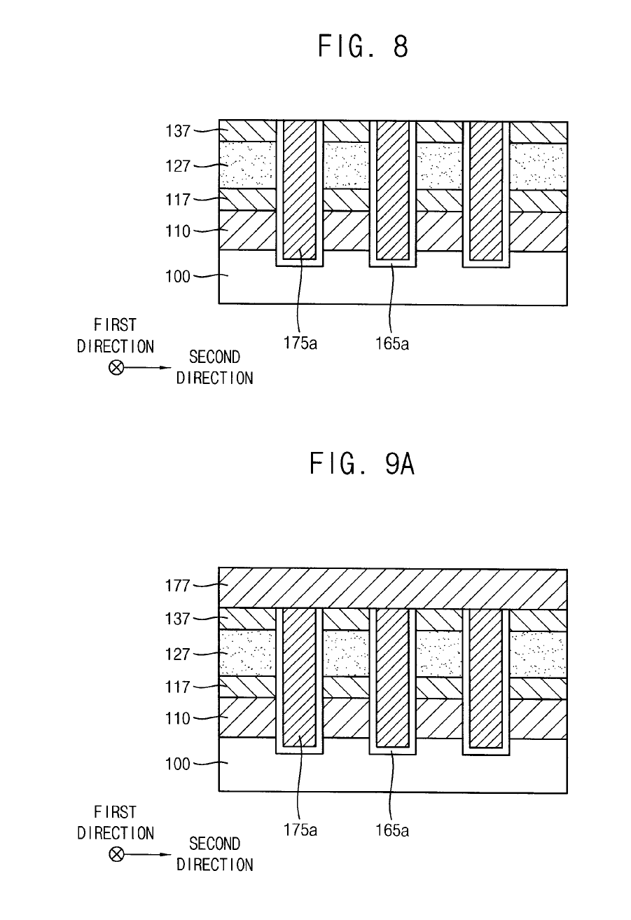

Referring to FIG. 8, the first thermal barrier layer 172 and the first insulation layer 162a may be planarized to form a first thermal barrier layer pattern 175a and a first insulation layer pattern 165a, respectively.

In particular, the first thermal barrier layer 172, the first insulation layer 162a and the first mask 139 may be planarized by a CMP process and/or an etch-back process, using the first mask 139 as a stop layer, until a top surface of the upper electrode layer pattern 137 is exposed. The first thermal barrier layer 172 and the first insulation layer 162a may be planarized to form the first thermal barrier layer pattern 175a and the first insulation layer pattern 165a, respectively, and the first mask 139 may be removed. The first thermal barrier layer pattern 175a and the first insulation layer 165a may extend in the first trench 145 in the first direction.

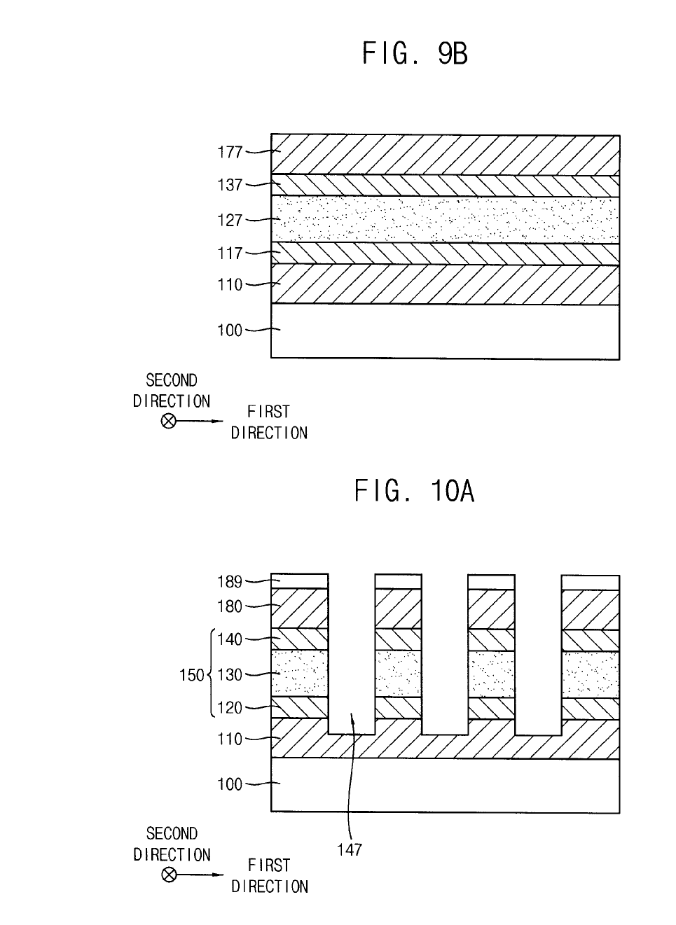

Referring to FIGS. 9A and 9B, a second conductive layer 177 may be formed on the upper electrode layer pattern 137, the first insulation layer pattern 165a and the first thermal barrier layer pattern 175a.

In particular, the second conductive layer 177 may be formed of metal, e.g., at least one metal selected from the group consisting of tungsten (W), copper (Cu), aluminum (Al), titanium (Ti), and tantalum (Ta). The second conductive layer 177 may be formed by a PVD process, a sputtering process, an ALD process, a CVD process or the like.

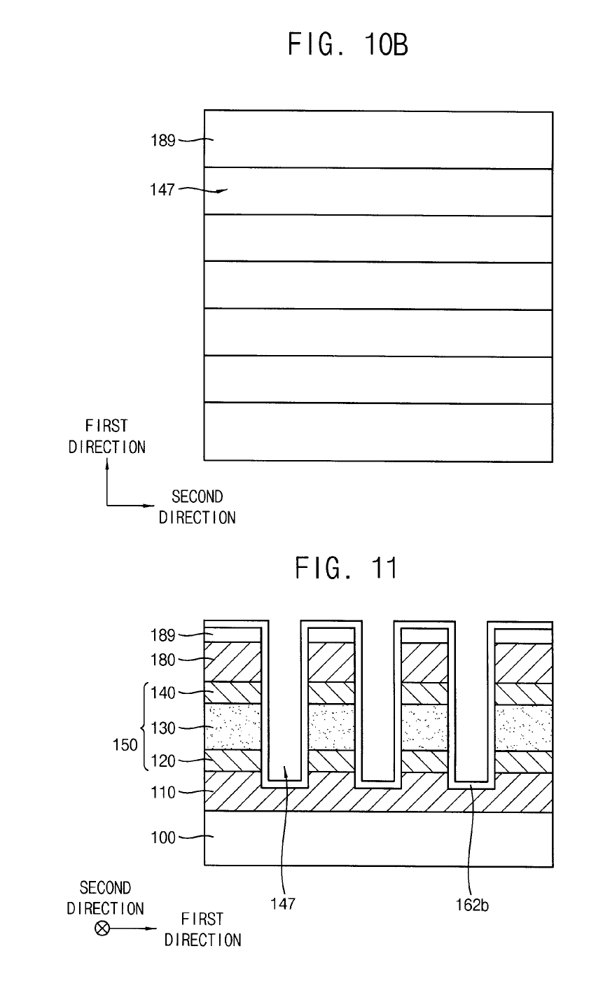

Referring to FIGS. 10A and 10B, a process similar to that illustrated with reference to FIG. 5 may be performed so that a second trench 147 may be formed through the second conductive layer 177, the upper electrode layer pattern 137, the variable resistance material layer pattern 127 and the lower electrode layer pattern 117, and the second trench 147 may be formed to expose an upper portion of the first conductive line 110.

In particular, a second mask 189 extending in the second direction may be formed to partially expose a top surface of the second conductive layer 177 on the second conductive layer 177. The second trench 14 may be formed through the second conductive layer 177, the upper electrode layer pattern 137, the variable resistance material layer pattern 127 and the lower electrode layer pattern 117 by a dry etching process using the second mask 189 as an etching mask. The second mask 189 may be formed of silicon nitride, for example. An upper portion of the first conductive line 110 may be also etched when the second trench 147 is formed by the etching process. The exposed first insulation layer pattern 165a and the first thermal barrier layer pattern 175a may be also partially removed by the etching process. Accordingly, a plurality of first insulation layer patterns 165a separated from each other by the second trench 147 and a plurality of first thermal barrier layer patterns 175a separated from each other by the second trench 147 may be formed.

In an embodiment according to the inventive concepts, the second trench 147 may extend in the second direction, and a plurality of second trenches 147 may be formed in the first direction. By the formation of the second trench 147, the lower electrode layer pattern 117, the variable resistance material layer pattern 127 and the upper electrode layer pattern 137 extending in the first direction may be transformed into a lower electrode 120, a variable resistance layer 130 and an upper electrode 140, respectively, each having an island-like shape.

The second conductive layer 177 may be transformed into a plurality of second conductive lines 180 by the formation of the second trench 147. The second conductive line 180 may extend in the second direction, and the plurality of second conductive lines 180 may be arranged in the first direction. Accordingly, the second conductive line 180 may be disposed over the first conductive line 110, and the first and second conductive lines 110 and 180 may cross or overlap each other. As illustrated in FIG. 2, a memory cell 150 may be formed at each intersection at which the first conductive line 110 and the second conductive line 180 cross or overlap each other.

In an embodiment according to the inventive concepts, the second conductive line 180 may serve as a bit line of the variable resistance memory device when the first conductive line 110 serves as a word line of the variable resistance memory device. Alternatively, the second conductive line 180 may serve as a word line of the variable resistance memory device when the first conductive line 110 serves as a bit line of the variable resistance memory device.

When the lower electrode layer pattern 117 is etched, an etching residue may remain on a top surface of the first conductive line 110 to cause interference between neighboring memory cells 150. In an embodiment according to the inventive concepts, however, the upper portion of the first conductive line 110 may be partially removed during the etching process for forming the second trench 147 so that the etching residue may be also removed. Therefore, a reliability of an operation of each memory cell 150 may be improved.

Referring to FIG. 11, a process similar to that illustrated with reference to FIG. 6 may be performed so that a second insulation layer 162b may be formed on the second mask 189 and on a sidewall and a bottom surface of the second trench 147.

The second insulation layer 162b may be formed of silicon nitride or silicon oxide, for example, by a CVD process or an ALD process.

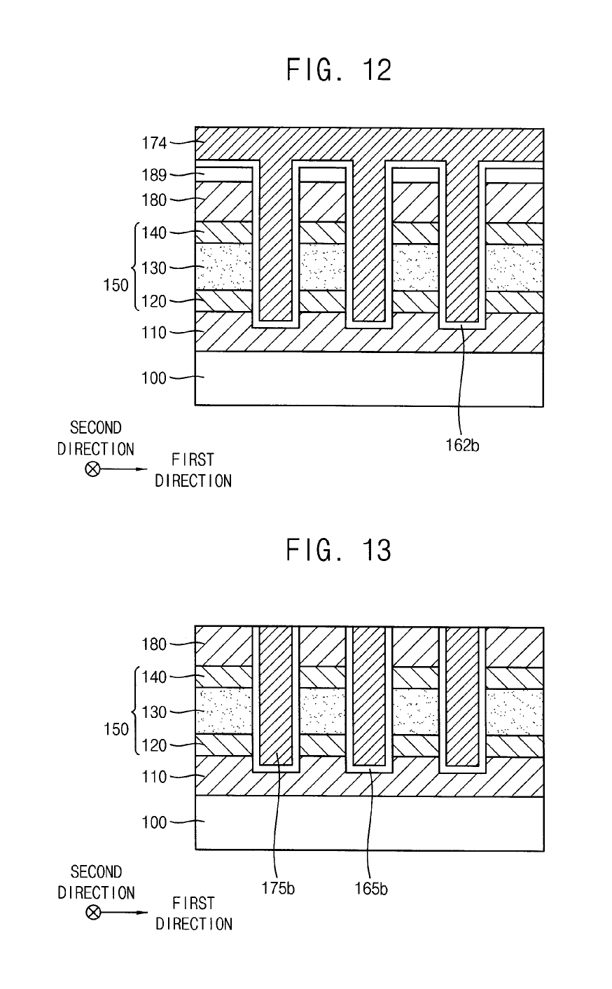

Referring to FIG. 12, a process similar to that illustrated with reference to FIG. 7 may be performed so that a second thermal barrier layer 174 may be formed on the second insulation layer 162b.

The second thermal barrier layer 174 may be formed on the second insulation layer 162b by a CVD process or an ALD process so that the second thermal barrier layer 174 may sufficiently fill the second trench 147.

In an embodiment according to the inventive concepts, the second thermal barrier layer 174 is formed of material having a thermal conductivity lower than that of the second insulation layer 162b. In an example of the present embodiment, the second thermal barrier layer 174 is formed of material having a thermal conductivity lower than silicon oxide, and the second insulation layer 162b is formed of silicon oxide. In an example of the present embodiment, the second thermal barrier layer 174 may be formed of substantially the same material as the first thermal barrier layer 172.

Referring to FIG. 13, a process similar to that illustrated with reference to FIG. 8 may be performed so that the second thermal barrier layer 174 and the second insulation layer 162b may be planarized to form a second thermal barrier layer pattern 175b and a second insulation layer pattern 165b, respectively.

In particular, the second thermal barrier layer 174, the second insulation layer 162b and the second mask 189 may be planarized by a CMP process and/or an etch-back process, using the second mask 189 as a stop layer, until a top surface of the second conductive line 180 is exposed. The second thermal barrier layer 174 and the second insulation layer 162b may be planarized to form the second thermal barrier layer pattern 175b and the second insulation layer pattern 165b, respectively. In this case, the second mask 139 may be removed. The second thermal barrier layer pattern 175b and the second insulation layer 165b may extend in the second trench 147 in the second direction. In an embodiment according to the inventive concepts, the first and second thermal barrier layer patterns 175a and 175b may define a thermal barrier layer pattern structure, and the first and second insulation layer patterns 165a and 165b may define an insulation layer pattern structure.

In an embodiment according to the inventive concepts, the first insulation layer pattern 165a and the first thermal barrier layer pattern 175a may extend in the first direction, and the second insulation layer pattern 165b and the second thermal barrier layer pattern 175b may extend in the second direction. A first structure including the first insulation layer pattern 165a and the first thermal barrier layer pattern 175a and a second structure including the second insulation layer pattern 165b and the second thermal barrier layer pattern 175b may cross each other.

According to the inventive concepts, the variable resistance memory device may be formed to include the thermal barrier layer pattern structure surrounded by the insulation layer pattern structure. The thermal barrier layer pattern structure may include a material having a thermal conductivity lower than that of the insulation layer pattern structure. Accordingly, heat transfer between the memory cells 150 may be decreased because of the thermal barrier layer pattern structure so that an operational reliability of the variable resistance memory device may be improved.

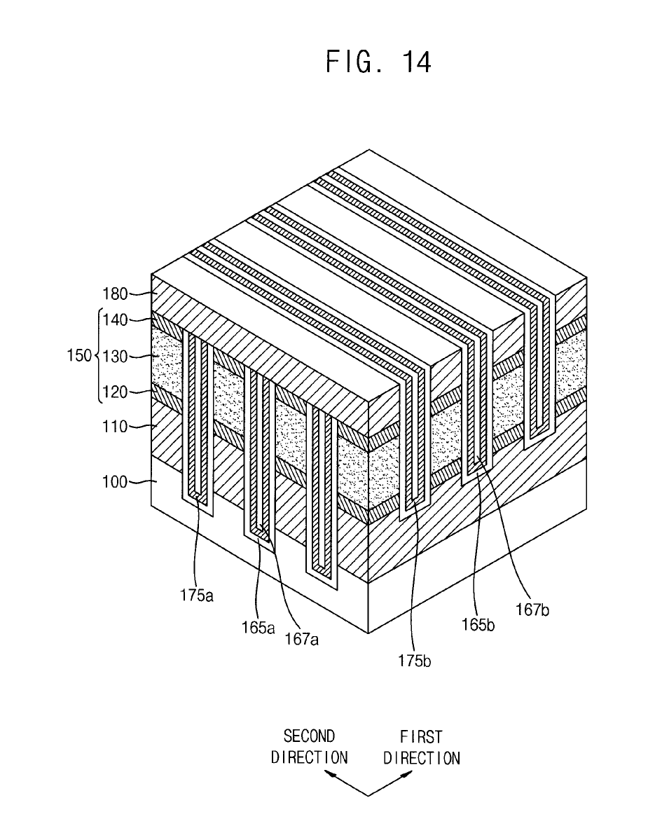

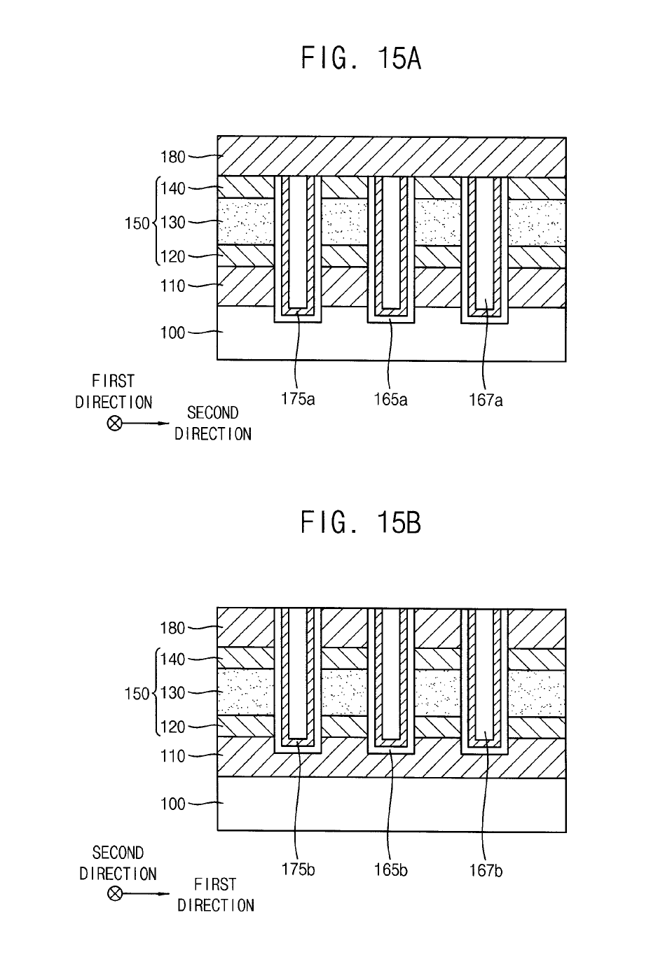

FIGS. 14, 15A and 15B are a perspective view and cross-sectional views illustrating a variable resistance memory device in accordance with the inventive concepts. The variable resistance memory device may be similar to that of FIGS. 1 to 3B, except for the shapes of the insulation layer pattern structure and the thermal barrier layer pattern structure. Thus, like reference numerals designate like elements, and repetitive explanations thereof may be omitted herein.

Referring to FIGS. 14, 15A and 15B, the variable resistance memory device may include a first conductive line 110, a second conductive line 180, a memory cell 150 and a thermal barrier layer pattern structure on a base insulation layer 100.

The thermal barrier layer pattern structure may be disposed between the memory cells 150. In an embodiment according to the inventive concepts, the thermal barrier layer pattern structure may include a first thermal barrier layer pattern 175a and a second thermal barrier layer pattern 175b.

The first thermal barrier layer pattern 175a may be formed between neighboring memory cell columns, and may extend in a first direction. The second thermal barrier layer pattern 175b may be formed between neighboring memory cell lows, and may extend in a second direction

As shown in FIGS. 15A and 15B, an insulation layer pattern structure may be formed on the thermal barrier layer pattern structure and a sidewall of the memory cell 150. In this embodiment according to the inventive concepts, the insulation layer pattern structure includes a first insulation layer pattern 165a covering the first thermal barrier layer pattern 175a, a second insulation layer pattern 165b covering the second thermal barrier layer pattern 175b, a third insulation layer pattern 167a on the first thermal barrier layer pattern 175a, and a fourth insulation layer pattern 167b on the second thermal barrier layer pattern 175b.

Accordingly, the first insulation layer pattern 165a, the first thermal barrier layer pattern 175a and the third insulation layer pattern 167a sequentially stacked between neighboring memory cells 150 may define a first insulation structure. The second insulation layer pattern 165b, the second thermal barrier layer pattern 175b and the fourth insulation layer pattern 167b sequentially stacked between neighboring memory cells 150 may define a second insulation structure.

The third and fourth insulation layer patterns 167a and 167b may include an insulating material, e.g., silicon oxide, silicon nitride or the like. These may be used alone or in a combination thereof. In an embodiment according to the inventive concepts, each of the third and fourth insulation layer patterns 167a and 167b may include substantially the same material as the first and second insulation layer patterns 165a and 165b.

According to the inventive concepts, the memory cells 150 of the variable resistance memory device may be surrounded by the thermal barrier layer pattern structure so that a heat transfer between the memory cells 150 may be decreased. Thus, an operational reliability of the variable resistance memory device may be improved.

FIGS. 16 to 21 are cross-sectional views illustrating stages of another embodiment of a method of manufacturing a variable resistance memory device in accordance with the inventive concepts. In particular, the figures may illustrate stages of a method of manufacturing the variable resistance memory device shown in FIGS. 14, 15A and 15B. Thus, like reference numerals designate like elements, this method may include processes similar to those illustrated with reference to FIGS. 4 to 13, and repetitive explanations thereof may be omitted herein.

Referring to FIG. 16, processes similar to those illustrated with reference to FIGS. 4 to 6 may be performed. Thus, a first trench 145a may be formed through an upper electrode layer 133, a variable resistance material layer 123, and the lower electrode layer 113. A first insulation layer 162a may be formed on a sidewall and a bottom surface of the first trench 145a and on a first mask 139.

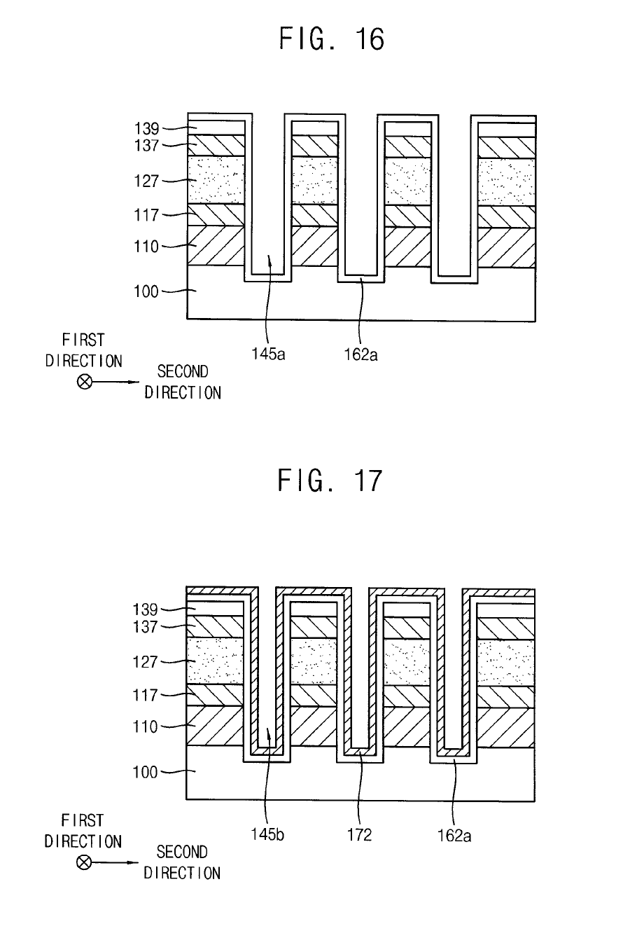

Referring to FIG. 17, processes similar to those illustrated with reference to FIGS. 7 to 8 may be performed. Thus, a first thermal barrier layer 172 may be formed on the first insulation layer 162a.

In particular, the first thermal barrier layer 172 may be formed along the first insulation layer 162a so that a first opening 145b may be defined by the first thermal barrier layer 172.

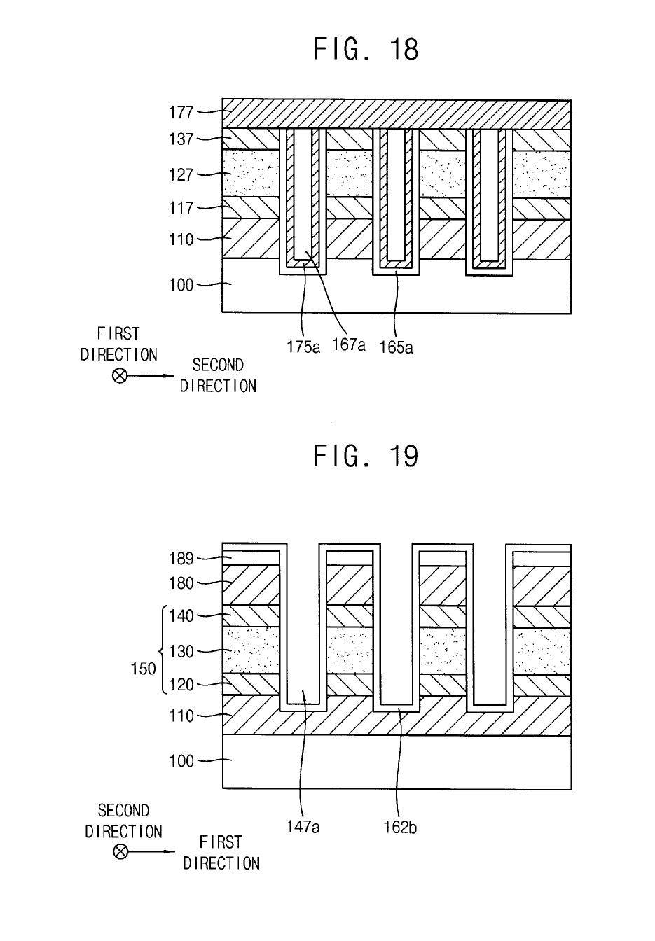

Referring to FIG. 18, a third insulation layer may be formed on the first thermal barrier layer 172. The third insulation layer, the first thermal barrier layer 172 and the first insulation layer 162a may be planarized to form a third insulation layer pattern 167a, a first thermal barrier layer pattern 175a and a first insulation layer pattern 165a, respectively.

In particular, the third insulation layer may be formed on the first thermal barrier layer 172 to sufficiently fill the first opening 145b, and the third insulation layer, the first thermal barrier layer 172 and the first insulation layer 162a may be planarized by a CMP process and/or an etch-back process until a top surface of the upper electrode layer pattern 137 is exposed. In this case, the first mask 139 may be removed, and the third insulation layer, the first thermal barrier layer 172 and the first insulation layer 162a may be planarized to form the third insulation layer pattern 167a, the first thermal barrier layer pattern 175a and the first insulation layer pattern 165a, respectively.

The third insulation layer, the first thermal barrier layer 172 and the first insulation layer 162a may extend in the first trench 145b in the first direction. The third insulation layer may be formed of insulating material, e.g., silicon oxide, silicon nitride or the like. The third insulation layer may be formed of material similar to that of the first insulation layer 162a.

Then, a process similar to that illustrated with reference to FIGS. 9A and 9B may be performed so that a second conductive layer 177 may be formed on the upper electrode layer pattern 137, the first insulation layer pattern 165a, the first thermal barrier layer pattern 175a and the third insulation layer pattern 167b.

Referring to FIG. 19, processes similar to those illustrated with reference to FIGS. 10A, 10B and 11 may be performed so that a second insulation layer 162b may be formed on a second mask 189 and on a sidewall and a bottom surface of a second trench 147a.

In particular, the second trench 147a may be formed through the second conductive layer 177, the upper electrode layer pattern 137, a variable resistance material layer pattern 127 and a lower electrode layer pattern 117 by a dry etching process using the second mask 189 as an etching mask. By the formation of the second trench 147, a second conductive line 180, and an upper electrode 140, a variable resistance layer 130, and a lower electrode 120 sequentially stacked on the first conductive line 110 may be formed to extend in the second direction. Then, the second insulation layer 162b may be formed on the second mask 189 and on the sidewall and the bottom surface of the second trench 147a.

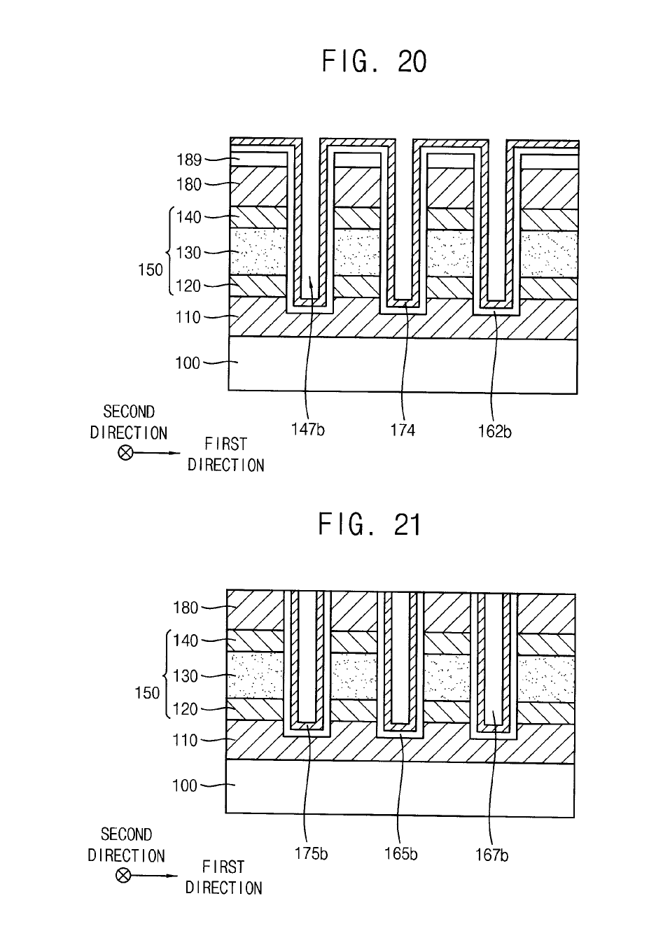

Referring to FIG. 20, processes similar to those illustrated with reference to FIGS. 12 and 13 may be performed so that a second thermal bather layer 174 may be formed on the second insulation layer 162b.

In particular, a second thermal barrier layer 174 may be formed on the second insulation layer 162b so that a second opening 147b may be defined by the second thermal barrier layer 174.

Referring to FIG. 21, a process similar to that illustrated with reference to FIG. 18 may be performed so that a fourth insulation layer pattern 167b, a second thermal barrier layer pattern 175b and a second insulation layer pattern 165b may be formed.

In particular, a fourth insulation layer may be formed on the second thermal barrier layer 174 to sufficiently fill the second opening 147b, and the fourth insulation layer, the second thermal barrier layer 174 and the second insulation layer 162b may be planarized by a CMP process and/or an etch-back process until a top surface of the second conductive line 180 is exposed. In this case, the second mask 180 may be removed, and the fourth insulation layer, the second thermal barrier layer 174 and second insulation layer 162b may be planarized to form a fourth insulation layer pattern 167a, the second thermal barrier layer pattern 175b and the second insulation layer pattern 165b, respectively. The fourth insulation layer pattern 167b, the second thermal barrier layer pattern 175b and the second insulation layer pattern 165b may extend in the second direction. The fourth insulation layer may be formed of insulating material, e.g., silicon oxide, silicon nitride or the like. The fourth insulation layer may be formed of material similar to that of the second insulation layer.

According to the inventive concepts, each of the first and second thermal barrier layer patterns 175a and 175b are formed of material having a thermal conductivity lower than those of the first to fourth insulation layer patterns 165a, 165b, 167a and 167b. Accordingly, heat transfer between the memory cells 150 may be decreased because of the first and second thermal barrier layer patterns 175a and 175b so that an operational reliability of the variable resistance memory device may be improved.

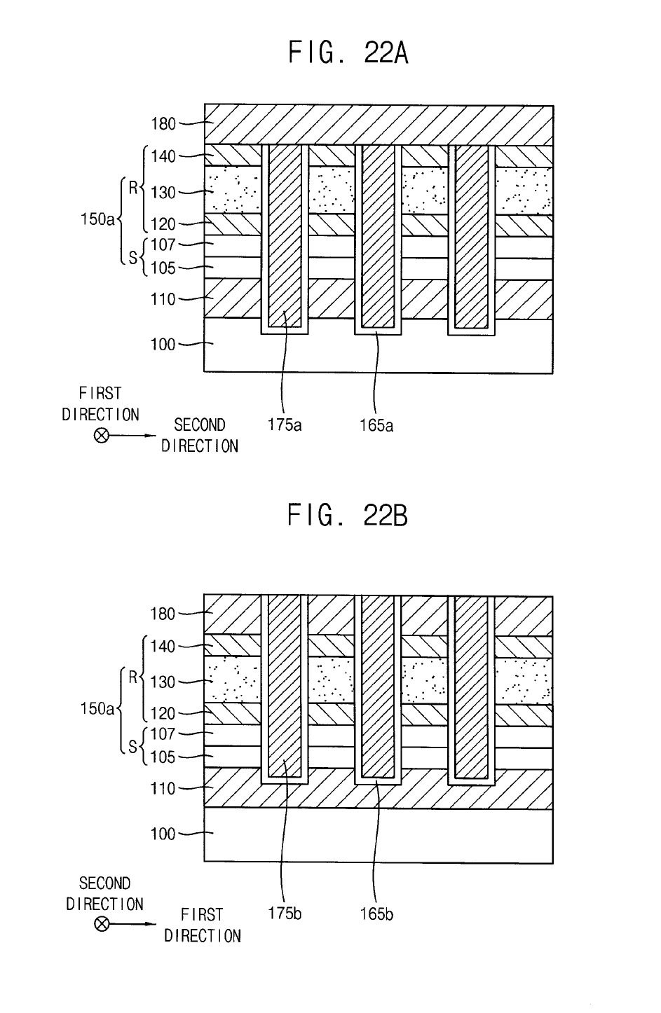

FIGS. 22A and 22B are cross-sectional views illustrating another embodiment of a variable resistance memory device in accordance with the inventive concepts.

For example, FIGS. 22A and 22B illustrate a variable resistance memory device having a cross-point memory cell array structure in which one selection element and one variable resistance element are formed at each intersection of conductive lines. The variable resistance memory device of FIGS. 22A and 22B may be other similar to that illustrated with reference to FIGS. 1 to 3B. Thus, like reference numerals designate like elements, and detailed descriptions thereof may be omitted herein.

Referring to FIGS. 22A and 22B, the variable resistance memory device may include a first conductive line 110, a second conductive line 180, a memory cell 150a and a thermal barrier layer pattern structure.

In an embodiment according to the inventive concepts, the variable resistance memory device may include a memory cell 150a at each intersection at which the first conductive line 110 and the second conductive line 180 cross each other. The memory cell 150a may have a structure in which a selection element S and a variable resistance element R are sequentially stacked.

The variable resistance element R may include a lower electrode 120, a variable resistance layer 130 and an upper electrode 140.

In an embodiment according to the inventive concepts, the selection element S may include a P-N diode. In this case, the selection element S may include a lower semiconductor layer pattern 105 and an upper semiconductor layer pattern 107 sequentially stacked on the first conductive line 110. For example, the lower semiconductor layer pattern 105 and the upper semiconductor layer pattern 107 may include polysilicon doped with n-type impurities and p-type impurities, respectively. In an example of the present embodiment, the selection element S may also include an insulation pattern (not shown) between the lower semiconductor layer pattern 105 and the upper semiconductor layer pattern 107, and in this case, the selection element S may be a P-I-N diode.

Alternatively, the lower semiconductor layer pattern 105 and the upper semiconductor layer pattern 107 may include an n-type oxide semiconductor and a p-type oxide semiconductor, respectively. The n-type oxide semiconductor may be a zinc oxide (ZnOx) or indium zinc oxide (InZnOx). The p-type oxide semiconductor may be a copper oxide (CuOx).

In an example of the present embodiment, a first buffer layer (not shown) may be interposed between the first conductive line 110 and the selection element S. A second buffer layer (not shown) may be interposed between the selection element S and the variable resistance element R. The first and second buffer layers may comprise a metal nitride, e.g., titanium nitride, tantalum nitride, tungsten nitride, or zirconium nitride.

The thermal barrier layer pattern structure may include a first thermal barrier layer pattern 175a and a second thermal barrier layer pattern 175b. The first and second thermal barrier layer patterns 175a and 175b may be disposed between neighboring memory cells 150, and may extend in the first and second directions, respectively.

An insulation layer pattern structure may be formed on a sidewall of the memory cell 150. In an embodiment according to the inventive concepts, the insulation layer pattern structure may include a first insulation layer pattern 165a covering the first thermal barrier layer pattern 175a, and a second insulation layer pattern 165b covering the second thermal barrier layer pattern 175b.

Each of the first insulation layer pattern 165a and the first thermal barrier layer pattern 175a may extend through an upper portion of the base insulation layer 100 so that lower portions of the first insulation layer pattern 165a and the first thermal barrier layer pattern 175a may be surrounded by the base insulation layer 100. Each of the second insulation layer pattern 165b and the second thermal barrier layer pattern 175b may extend through an upper portion of the first conductive line 110 so that lower portions of the second insulation layer pattern 165b and the second thermal barrier layer pattern 175b may be surrounded by the first conductive line 110.

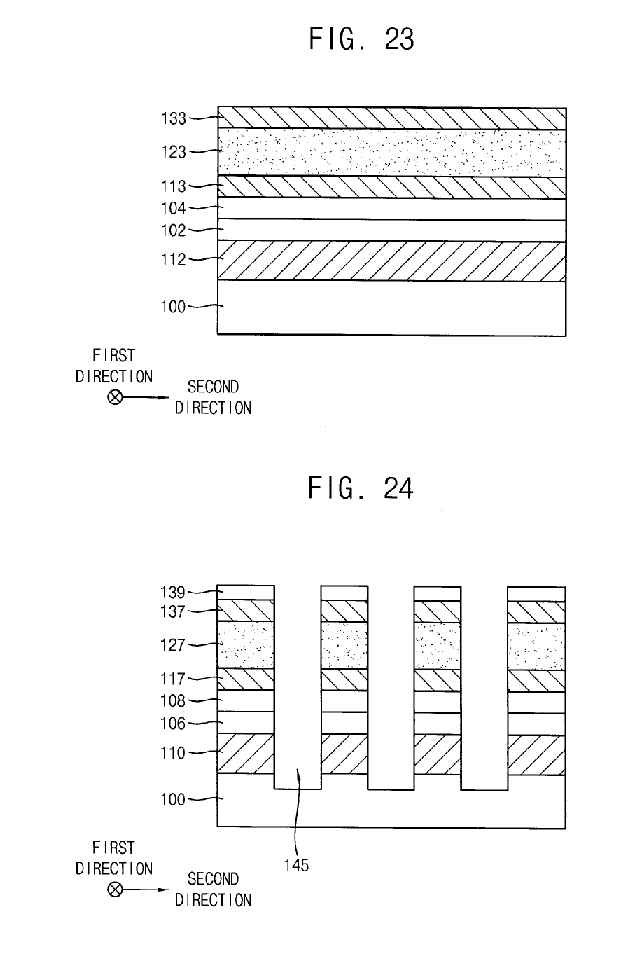

FIGS. 23 to 27 illustrate stages of a method of manufacturing a variable resistance memory device in accordance with the inventive concepts. The method may be used to manufacture the variable resistance memory device shown in FIGS. 22A and 22B but is not be limited thereto. This method may include processes similar to those illustrated with reference to FIGS. 4 to 13, and thus like reference numerals designate like elements, and repetitive explanations thereof may be omitted herein.

Referring to FIG. 23, a first conductive layer 112, a lower semiconductor layer 102, an upper semiconductor layer 104, a lower electrode layer 113, a variable resistance material layer 123 and an upper electrode layer 133 may be sequentially formed on a base insulation layer 100.

The lower semiconductor layer 102 may be formed of polysilicon doped with n-type impurities, e.g., phosphorous (P) or arsenic (As). In an example of the present embodiment, an amorphous silicon layer may be deposited, and n-type impurities may be implanted therein. A crystallization process, e.g., a laser annealing process, may be performed on the amorphous silicon layer to form the lower semiconductor layer 102. Alternatively, the lower semiconductor layer 102 may be formed of n-type oxide semiconductor, e.g., zinc oxide, indium zinc oxide or the like.

The upper semiconductor layer 104 may be formed of polysilicon doped with p-type impurities, e.g., boron (B), gallium (Ga) or the like. In an example of the present embodiment, an amorphous silicon layer may be deposited, and p-type impurities may be implanted therein. A crystallization process, e.g., a laser annealing process, may be performed on the amorphous silicon layer to form the upper semiconductor layer 104. Alternatively, the upper semiconductor layer 104 may be formed of a p-type oxide semiconductor, e.g., copper oxide.

Each of the lower and upper semiconductor layers 102 and 104 may be formed by a PVD process, a sputtering process, an ALD process or the like.

In an example of the present embodiment, a first buffer layer (not shown) may be Furthermore formed between the first conductive layer 112 and the lower semiconductor layer 102. Additionally, a second buffer layer (not shown) may be formed between the upper semiconductor layer 104 and the lower electrode layer 115. The first and second buffer layers may be formed of a metal nitride, e.g., titanium nitride, tantalum nitride, tungsten nitride, or zirconium nitride, by a PVD process, a sputtering process or an ALD process.

Referring to FIG. 24, a process similar to that illustrated with reference to FIG. 5A may be performed to form a first trench 145 exposing an upper portion of the base insulation layer 100.

In an embodiment according to the inventive concepts, the first trench 145 may extend in the first direction, and a plurality of first trenches 145 may be formed in the second direction. The upper portion of the base insulation layer 100 may be over-etched when the first trench 145 is formed.

By the formation of the first trench 145, a first conductive line 110, a lower semiconductor layer line 106, an upper semiconductor layer line 108, a lower electrode layer pattern 117, a variable resistance material layer pattern 127 and an upper electrode layer pattern 137, each of which may extend in the first direction, may be sequentially formed on the base insulation layer 100.

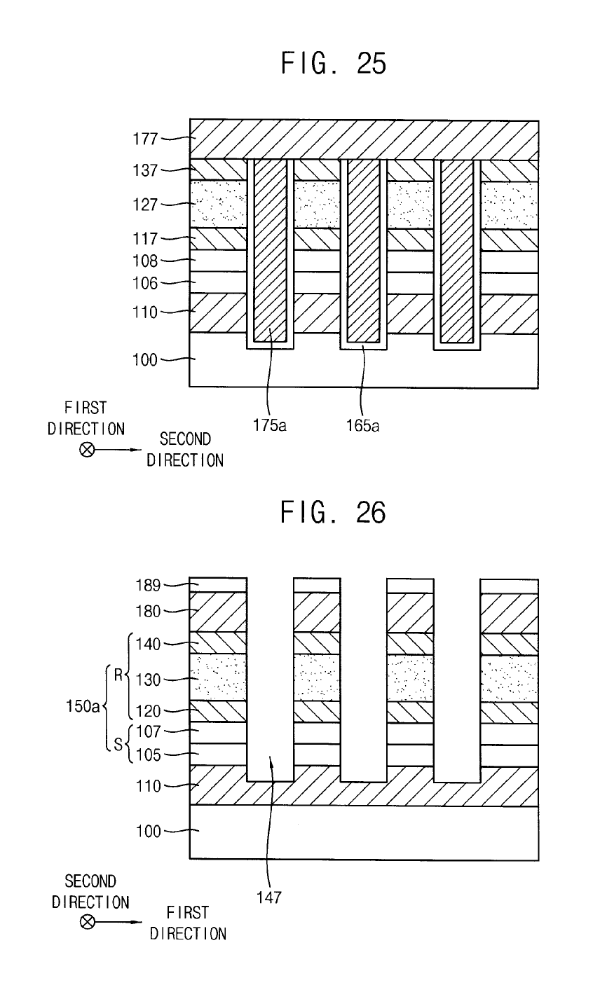

Referring to FIG. 25, processes similar to those illustrated with reference to FIGS. 6 to 8 may be performed.

Accordingly, a first insulation layer pattern 165a and a first thermal barrier layer pattern 175a filling the first trench 145 may be formed on a sidewall and a bottom surface of the first trench 145. After forming the first insulation layer pattern 165a and the first thermal barrier layer pattern 175a, a first mask 139 may be removed. A second conductive layer 177 may be formed on the upper electrode layer pattern 137, the first insulation layer pattern 165a and the first thermal barrier layer pattern 175a.

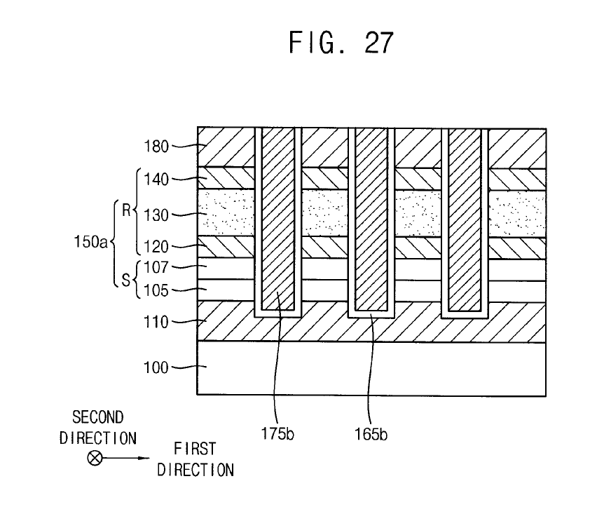

Referring to FIG. 26, a process similar to that illustrated with reference to FIGS. 9A to 9B may be performed.

Accordingly, a second trench 147 extending in the second direction may be formed through the second conductive layer 177, the upper electrode layer pattern 137, the variable resistance material layer pattern 127, the lower electrode layer pattern 117, the upper semiconductor layer line 108 and the lower semiconductor layer line 106. In an embodiment according to the inventive concepts, a plurality of second trenches 147 may be formed in the first direction. An upper portion of the first conductive line 110 may be over-etched during the process for forming the second trench 147.

By the formation of the second trench, a second conductive line 180 extending in the second direction may be formed. Furthermore, the upper electrode layer pattern 137, the variable resistance material layer pattern 127, the lower electrode layer pattern 117, the upper semiconductor layer line 108 and the lower semiconductor layer line 106 may be transformed into an upper electrode 140, a variable resistance layer 130, a lower electrode 120, an upper semiconductor layer pattern 107 and a lower semiconductor layer pattern 105, respectively.

A variable resistance element R may be defined by the lower electrode 120, the variable resistance layer 130 and the upper electrode 140. A selection element S may be defined by the lower semiconductor layer pattern 105 and the upper semiconductor layer pattern 107. Accordingly, a memory cell 150a including the selection element S and the variable resistance element R may be formed at an intersection of the first and second conductive lines 110 and 180.

Referring to FIG. 27, processes similar to those illustrated with reference to FIGS. 10A to 13 may be performed.

Accordingly, a second insulation layer pattern 165b and a second thermal barrier layer pattern 175b filling the second trench 147 may be formed on a sidewall and a bottom surface of the second trench 147. The second mask 199 may be removed.

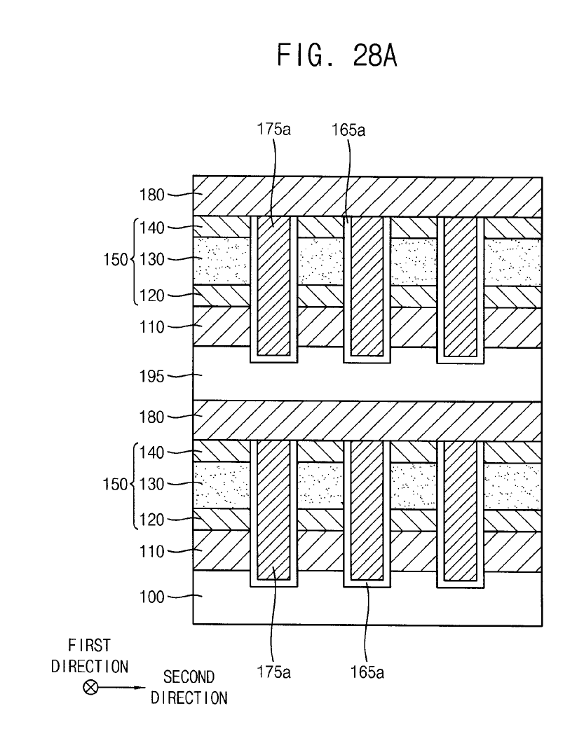

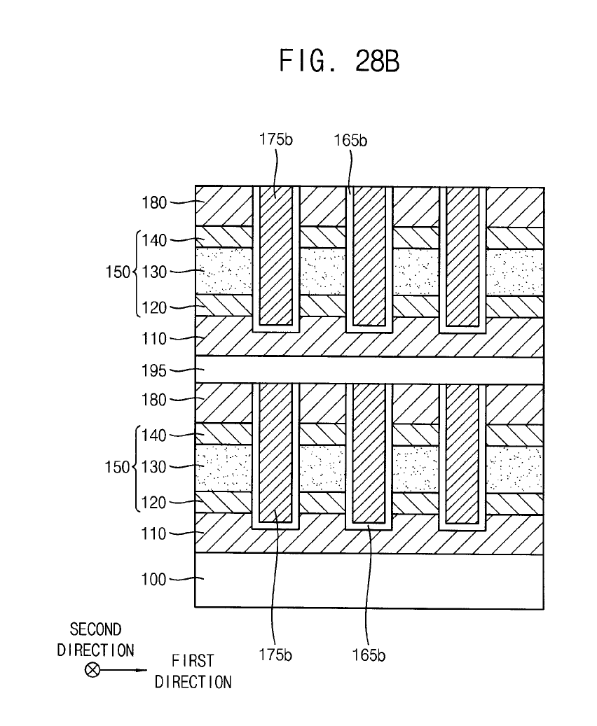

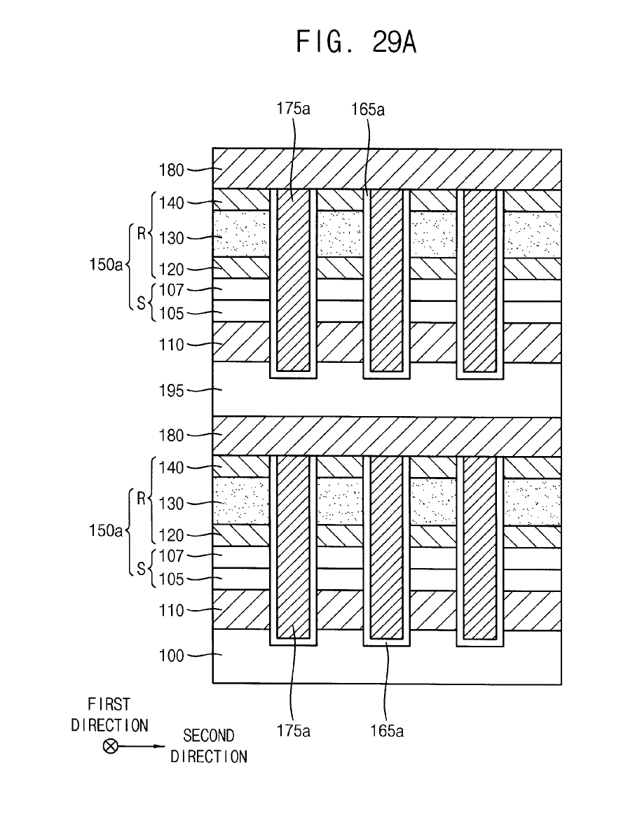

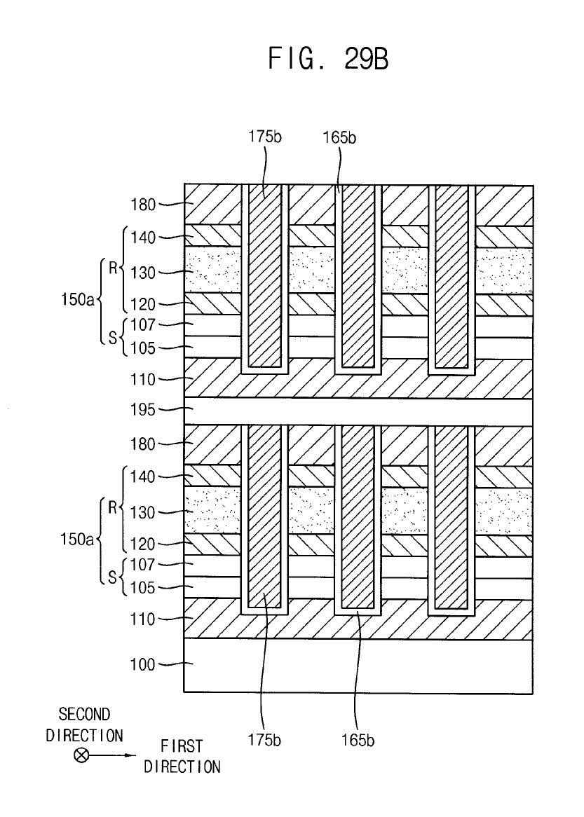

FIGS. 28A, 28B, 29A and 29B are cross-sectional views illustrating stacked variable resistance memory devices in accordance with the inventive concepts. Specifically, FIGS. 28A and 28B illustrate a stacked variable resistance memory device which may include two of the variable resistance memory devices shown in FIGS. 1 to 3B sequentially stacked. FIGS. 29A and 29B illustrate a stacked variable resistance memory device which may include two of the variable resistance memory devices shown in FIGS. 22A and 22B sequentially stacked. Thus, like reference numerals designate like elements, and repetitive explanations thereof may be omitted herein.

Referring to FIGS. 28A and 28B, the stacked variable resistance memory device may include a first variable resistance memory device and a second variable resistance memory device sequentially stacked.

In an embodiment according to the inventive concepts, each of the first and second variable resistance memory devices may be similar to that illustrated with reference to FIGS. 1 to 3B. For example, each of the first and second variable resistance memory devices may have a structure in which one variable resistance element is formed at an intersection of a first conductive line 110 and a second conductive line 180.

An insulating interlayer 195 may be formed between the first and second variable resistance memory devices. A first insulation layer pattern 165a and a first thermal barrier layer pattern 175a may extend through an upper portion of the insulating interlayer 195 so that lower portions of the first insulation layer pattern 165a and the first thermal barrier layer pattern 175a may be surrounded by the insulating interlayer 195.

Referring to FIGS. 29A and 29B, the stacked variable resistance memory device may have a stacked structure in which a first variable resistance memory device and a second variable resistance memory device may be sequentially stacked. The first and second variable resistance memory devices each may be similar to that illustrated with reference to FIGS. 22A and 22B. For example, each of the first and second variable resistance memory devices may have a structure in which one selection element S and one variable resistance element R are formed at an intersection of a first conductive line 110 and a second conductive line 180.

FIGS. 28A to 29B illustrate stacked variable resistance memory devices each of which has only two stacked variable resistance memory devices sequentially. However, the stacked variable resistance memory may have at least three stacked variable resistance memory devices.

The stacked variable resistance memory devices of FIGS. 28A and 28B, or FIGS. 29A and 29B may be manufactured by repeatedly performing processes similar to those illustrated with reference to FIGS. 4 to 13 or FIGS. 23 to 27. Thus, detailed descriptions on methods of manufacturing the stacked variable resistance memory devices are omitted herein.

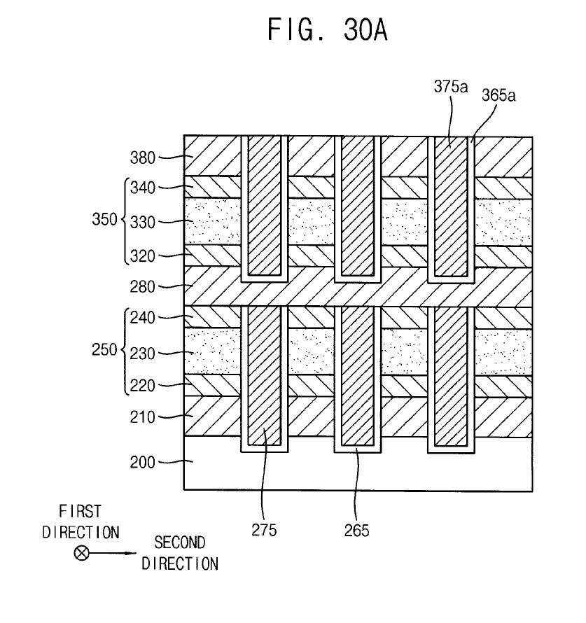

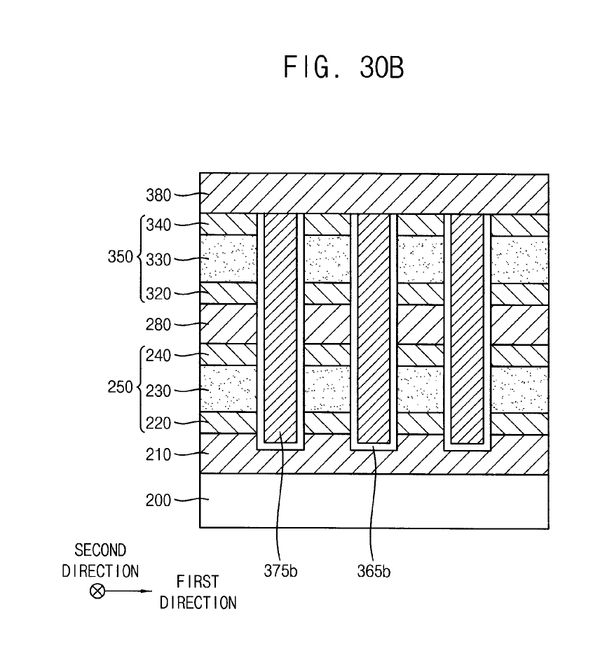

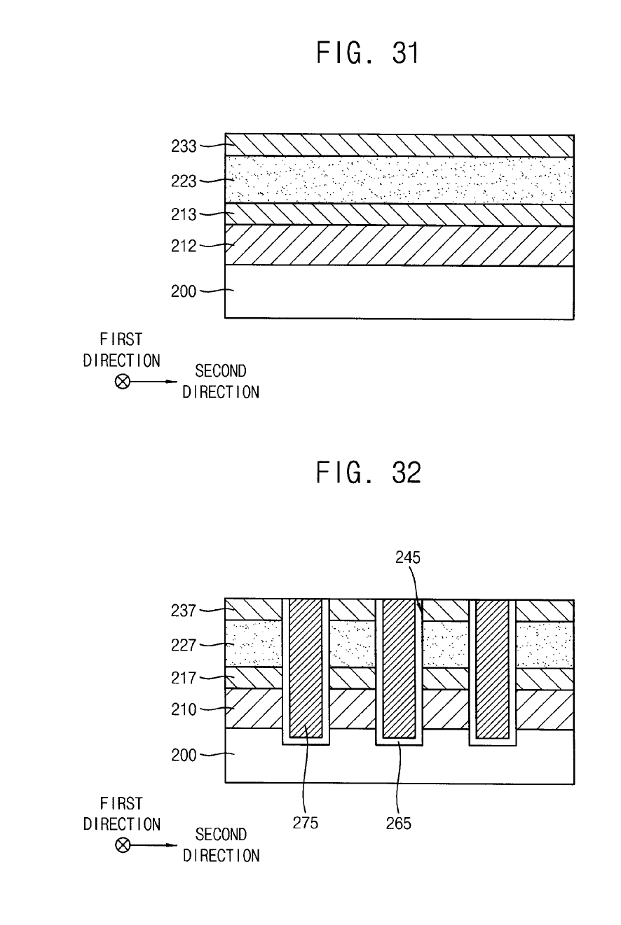

FIGS. 30A and 30B are cross-sectional views illustrating another embodiment of a stacked variable resistance memory device in accordance with the inventive concepts. Specifically, FIGS. 30A and 30B are cross-sectional views taken along a second direction and a first direction, respectively.

FIGS. 30A and 30B illustrate an example in which the stacked variable resistance memory device has first and second stacked variable resistance memory devices, each of which may include one variable resistance element formed at an intersection of conductive lines. Each of the first variable resistance memory device and second variable resistance memory device may thus be similar to that of FIGS. 1 to 3B. Thus, like reference numerals designate like elements, and repetitive explanations thereof may be omitted herein.

Referring to FIGS. 30A and 30B, the stacked variable resistance memory device may include a first conductive line 210, a second conductive line 280 and a third conductive line 380, a first memory cell 250, a second memory cell 350 and a thermal barrier layer pattern structure sequentially stacked on a base insulation layer 200.

The first memory cell 250 may be formed at an intersection of the first and second conductive lines 210 and 280

In an embodiment according to the inventive concepts, a plurality of first conductive lines 210, a plurality of second conductive lines 280, and a plurality of third conductive lines 380 may be formed. The first memory cell 250 may be formed at an intersection of the first and second conductive lines 210 and 280, and the second memory cell 350 may be formed at an intersection of the first and second conductive lines 280 and 380.

The first conductive line 210 may extend in the first direction, and the plurality of first conductive lines 210 may be arranged in the second direction. The second conductive line 280 may be disposed over the first conductive line 210. The second conductive line 280 may extend in the second direction, and the plurality of second conductive lines 280 may be arranged in the first direction. The third conductive line 380 may be disposed over the second conductive line 280. The third conductive line 380 may extend in the first direction, and the plurality of third conductive lines 380 may be arranged in the second direction. Accordingly, the first and third conductive lines 210 and 380 may extend in substantially the same direction, and the second conductive line 280 may cross or overlap the first and third conductive lines 210 and 380 therebetween.

In an embodiment according to the inventive concepts, the first and third conductive lines 210 and 380 may serve as bit lines or word lines of the stacked variable resistance memory device. The second conductive line 280 may serve as a common word line of the stacked variable resistance memory device when the first and third conductive lines 210 and 380 serve as the bit lines. Alternatively, the second conductive line 280 may serve as a common bit line of the stacked variable resistance memory device when the first and third conductive lines 210 and 380 serve as word lines.

As the plurality of first conductive lines 210, the plurality of second conductive lines 280, and the plurality of third conductive lines 380 are formed, a plurality of first memory cells 250 may be formed at an intersection at which the first and third conductive lines 210 and 380 overlap or cross each other. A plurality of second memory cells 350 may be formed at an intersection at which the second and third conductive lines 280 and 380 overlap or cross each other. The plurality of first memory cells 250 and the plurality of second memory cells 350 may be arranged in the first direction to form a first memory cell column and a second memory cell column, respectively. The plurality of first memory cells 250 and the plurality of second memory cells 350 may be arranged in the second direction to form a first memory cell row and a second memory cell row, respectively.

In an embodiment according to the inventive concepts, the first memory cell 250 may include a first variable resistance layer 230. In an embodiment according to the inventive concepts, a first lower electrode 220 may be formed between the first variable resistance layer 230 and the first conductive line 210, and a first upper electrode 240 may be formed between the first variable resistance layer 230 and the second conductive line 280. The first variable memory device may be defined by the first conductive line 210, the first memory cell 250 and the second conductive line 280.

In an embodiment according to the inventive concepts, the second memory cell 350 may include a second variable resistance layer 330. In an embodiment according to the inventive concepts, a second lower electrode 320 may be formed between the second variable resistance layer 330 and the second conductive line 280, and a second upper electrode 340 may be formed between the second variable resistance layer 330 and the third conductive line 380. The second variable memory device may be defined by the second conductive line 280, the second memory cell 350 and the third conductive line 380.

The thermal barrier layer pattern structure may be formed between the first and second memory cells 250 and 350. In an embodiment according to the inventive concepts, the thermal barrier layer pattern structure may include a first thermal barrier layer pattern 275, a second thermal barrier layer pattern 375a and a common thermal barrier layer pattern 375b.

The first thermal barrier layer pattern 275 may be formed between neighboring first memory cell columns, and may extend in the first direction. The first thermal barrier layer pattern 275 may extend through the first memory cells 250 and the first conductive lines 210 adjacent in the second direction. In an embodiment according to the inventive concepts, the first thermal barrier layer pattern 275 may extend through an upper portion of the base insulation layer 200 so that a lower portion of the first thermal barrier layer pattern 275 may be surrounded by the base insulation layer 200.

The second thermal barrier layer pattern 375a may be formed between neighboring second memory cell columns, and may extend in the first direction. The second thermal barrier layer pattern 375a may extend through the second memory cells 350 and the second conductive lines 280 adjacent in the second direction. In an embodiment according to the inventive concepts, the second thermal barrier layer pattern 375a may extend through an upper portion of the second conductive line 280 so that a lower portion of the second thermal barrier layer pattern 375a may be surrounded by the second conductive line 280.

The common thermal barrier layer pattern 375b may be formed between neighboring first and second memory cell rows, and may extend in the second direction. The common thermal barrier layer pattern 375b may extend through the second memory cells 350, the second conductive lines 280, the first memory cells 250 adjacent in the first direction. In an embodiment according to the inventive concepts, the common thermal barrier layer pattern 375b may extend through an upper portion of the first conductive line 210 so that a lower portion of the common thermal barrier layer pattern 375b may be surrounded by the first conductive line 210.

In an embodiment according to the inventive concepts, the first thermal barrier layer pattern 275 and the common thermal barrier layer pattern 375b may cross each other, and may be in communication with each other. The second thermal barrier layer pattern 375a and the common thermal barrier layer pattern 375b may also cross each other, and may be in communication with each other. Thus, the first and second thermal barrier layer patterns 275 and 375a may be in communication with each other via the common thermal barrier layer pattern 375b.

Accordingly, sidewalls of the first and second memory cells 250 and 350 may be surrounded by an insulation layer pattern structure. In an embodiment according to the inventive concepts, the insulation layer pattern structure may include a first insulation layer pattern 265 covering the first thermal barrier layer pattern 275, a second insulation layer pattern 365a covering the second thermal barrier layer pattern 375a and a common insulation layer pattern 365b covering the common thermal barrier layer pattern 375b. The insulation layer pattern structure comprises insulating material, e.g., silicon oxide, silicon nitride or the like.

The first and second insulation layer patterns 265 and 365a may cover sidewalls and bottom surfaces of the first and second thermal barrier layer patterns 275 and 375a, respectively, and may extend in the first direction. The common insulation layer pattern 365b may cover a sidewall and a bottom surface of the common thermal barrier layer pattern 375b, and may extend in the second direction.

The first thermal barrier layer pattern 275 and the common thermal barrier layer pattern 375b may be separated by the first insulation layer pattern 265 and the common insulation layer patterns 365b, respectively, from the first memory cells 250 adjacent thereto. The second thermal barrier layer pattern 375a and the common thermal barrier layer pattern 375b may be separated by the second insulation layer pattern 365a and the common insulation layer patterns 365b, respectively, from the second memory cells 350 adjacent thereto.

A sidewall of the first memory cell 250 may be surrounded by the first insulation layer pattern 265 and the common insulation layer pattern 365b, and the plurality of first memory cells 250 may have an island-like shape delimited by the first thermal barrier layer pattern 275 and the common thermal barrier layer pattern 375b. A sidewall of the second memory cell 350 may be surrounded by the second insulation layer pattern 365a and the common insulation layer pattern 365b, and the plurality of second memory cells 350 may have an island-like shape delimited by the second thermal barrier layer pattern 375a and the common thermal barrier layer pattern 375b.

According to the inventive concepts, the first and second memory cells 250 and 350 may be surrounded by the first and second thermal barrier layer patterns 275 and 375a and the common thermal barrier layer pattern 375b, and heat transfer between the first and second memory cells 250 and 350 may be decreased so that an operational reliability of the stacked variable resistance memory device may be improved. The common thermal barrier layer pattern 375b extending in the second direction may be formed commonly through the first and second variable resistance memory devices. Thus, the structure of the stacked variable resistance memory device and the method of manufacturing the stacked variable resistance memory device may be simplified.

FIGS. 31 to 37 are cross-sectional views illustrating stages of a method of manufacturing a stacked variable resistance memory device in accordance with the inventive concepts. The method may be used to manufacture a stacked variable resistance memory device as shown in FIGS. 30A and 30B; however, the method is not limited thereto. Also, this method may include processes similar to those illustrated with reference to FIGS. 4 to 13, and thus like reference numerals designate like elements, and repetitive explanations thereof may be omitted herein.

Referring to FIG. 31, a process similar to that illustrated with reference to FIG. 4 may be performed so that a first conductive layer 212, a first lower electrode layer 213, a first variable resistance material layer 223 and a first upper electrode layer 233 may be sequentially formed on a base insulation layer 200.

Referring to FIG. 32, processes similar to those illustrated with reference to FIGS. 5A to 8 may be performed so that a first trench 245 extending in a first direction may be formed through the first upper electrode layer 233, the first variable resistance material layer 223, the first lower electrode layer 213 and the first conductive layer 212. A first insulation layer 245 may be formed on a sidewall and a bottom surface of the first trench 245. A first thermal barrier layer pattern 275 filling the first trench 245 may be formed on the first insulation layer 245. By forming the first trench 245, an upper portion of the base insulation layer 200 may be also etched.

By the formation of the first trench 245, the first conductive layer 212, the first lower electrode layer 213, the first variable resistance material layer 223 and the first upper electrode layer 233 may be transformed into a first conductive line 210, a first lower electrode layer pattern 217, a first variable resistance material layer pattern 227 and a first upper electrode layer pattern 237, respectively.

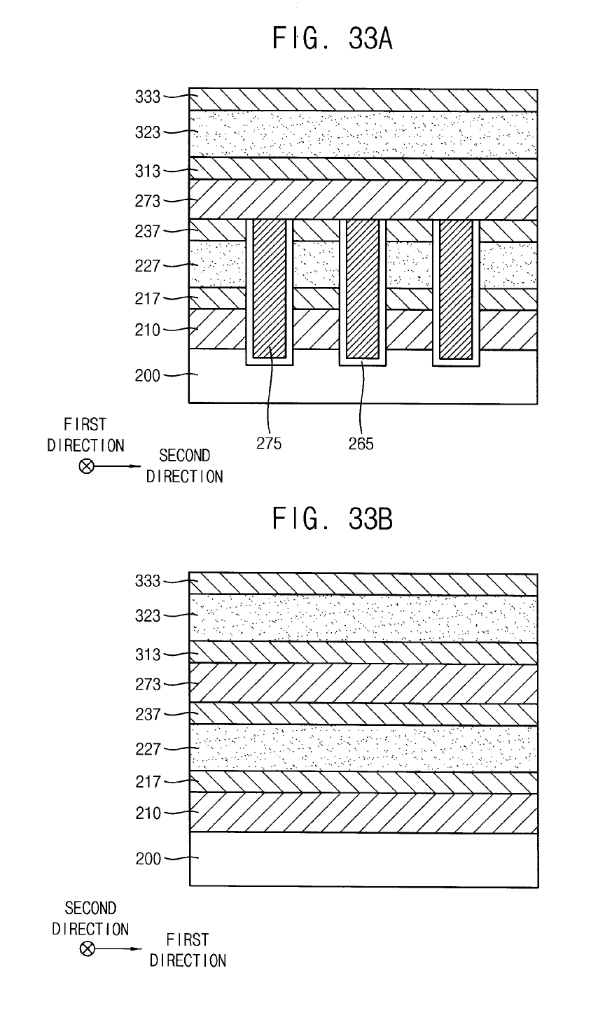

Referring to FIGS. 33A and 33B, a process similar to that illustrated with reference to FIG. 31 may be performed so that a second conductive layer 273, a second lower electrode layer 313, a second variable resistance material layer 323 and a second upper electrode layer 333 may be sequentially formed on the first upper electrode layer pattern 237, the first insulation layer pattern 265 and the first thermal barrier layer pattern 275.

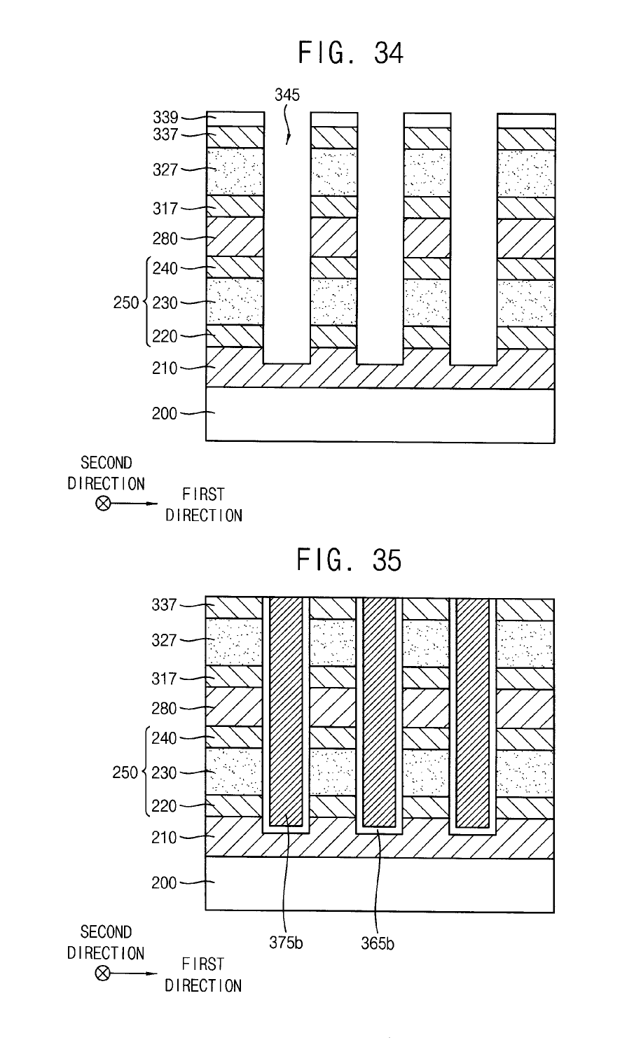

Referring to FIG. 34, a common trench 345 may be formed through the second upper electrode layer 333, the second variable resistance material layer 323, the second lower electrode layer 313, the second conductive layer 273, the first upper electrode layer pattern 237, the first variable resistance material layer pattern 227 and the first lower electrode layer pattern 217. In an embodiment according to the inventive concepts, the common trench 345 may extend in the second direction, and a plurality of common trenches 345 may be formed in the first direction.

For example, a second mask 339 extending in the second direction may be formed on the second upper electrode layer 333 to partially expose a top surface of the second upper electrode layer 333. The common trench 345 may be formed through the second upper electrode layer 333, the second variable resistance material layer 323, the second lower electrode layer 313, the second conductive layer 273, the first upper electrode layer pattern 237, the first variable resistance material layer pattern 227 and the first lower electrode layer pattern 217 by a dry etching process using the second mask 339 as an etching mask. Furthermore, portions of the first insulation layer pattern 265 and the first thermal barrier layer pattern 275 may be also removed during the etching process.

In an embodiment according to the inventive concepts, an upper portion of the first conductive line 120 may be also etched when the common trench 345 is formed.

By the formation of the common trench 345, the first lower electrode layer pattern 217, the first variable resistance material layer pattern 227, the first upper electrode layer pattern 237 and the second conductive layer 273 may be transformed into a first lower electrode 220, a first variable resistance layer 230, a first upper electrode 240 and a second conductive line 280, respectively. Accordingly, a first memory cell 250 may be defined by the first lower electrode 220, the first variable resistance layer 230 and the first upper electrode 240. A first variable resistance memory device may be defined by the first conductive lines 210, the first memory cells 250 and the second conductive lines 280.

By the formation of the common trench 345, the second lower electrode layer 313, the second variable resistance material layer 323 and the second upper electrode layer 333 may be transformed into a second lower electrode layer pattern 317, a second variable resistance material layer pattern 327 and the second upper electrode layer pattern 337, respectively.

Referring to FIG. 35, a common insulation layer pattern 365b may be formed on a sidewall and a bottom surface of the common trench 345, and a common thermal barrier layer pattern 375b filling a remaining portion of the common trench 345 may be formed on the common insulation layer pattern 365b.

In an embodiment according to the inventive concepts, processes similar to those illustrated with reference to FIGS. 11 and 13 may be performed so that a common insulation layer may be formed on a second mask 339, and a common thermal barrier layer sufficiently filling the common trench 345 may be formed on the common insulation layer.

In an embodiment according to the inventive concepts, the common thermal barrier layer is formed to include material having a thermal conductivity lower than that of the common insulation layer. In an example of the present embodiment, the common thermal barrier layer may be formed of material having a thermal conductivity lower than silicon oxide and the common insulation layer may be formed of silicon oxide. The common thermal barrier layer may be formed of material similar to that of the first thermal barrier layer pattern 275.

The common insulation layer and the common thermal barrier layer may be planarized until the top surface of the second upper electrode layer pattern 337 is exposed to form the common insulation layer pattern 365b and the common thermal barrier layer pattern 375b, respectively. The second mask 339 may be removed.

In an embodiment according to the inventive concepts, the common thermal barrier layer pattern 375b and the first thermal barrier layer pattern 275 may cross each other, and may be connected to each other.

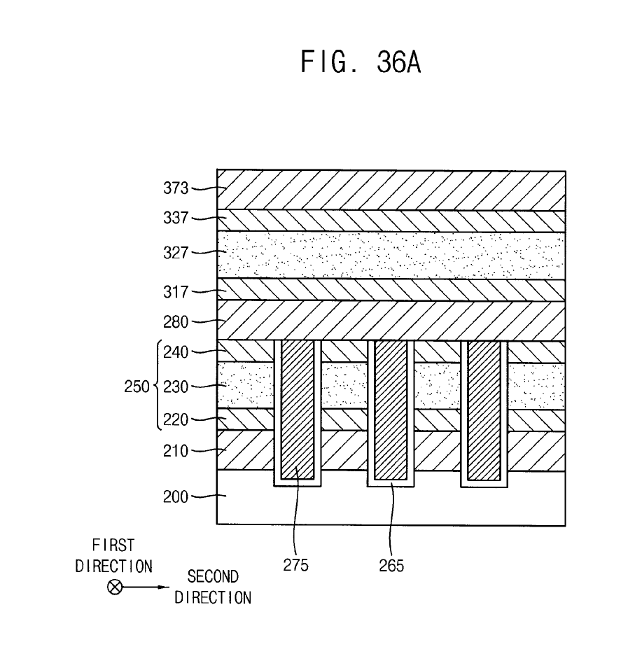

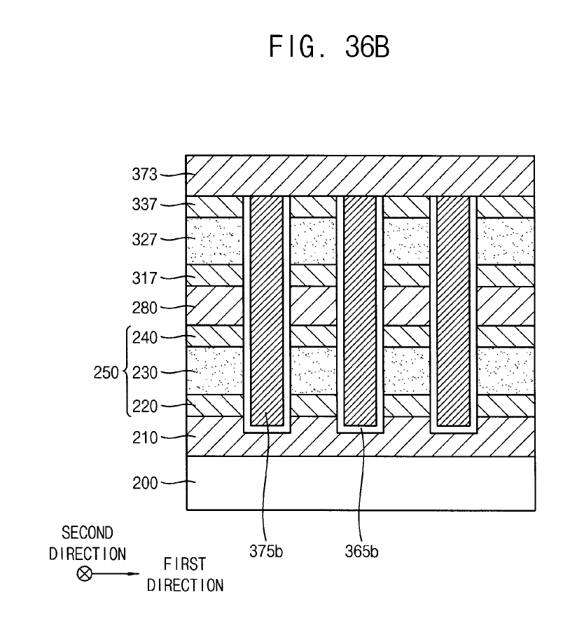

Referring to FIGS. 36A and 36B, a third conductive layer 373 may be formed on the second upper electrode layer pattern 337, the common insulation layer pattern 365b and the common thermal barrier layer pattern 375b. The third conductive layer 373 may be formed of metal, e.g., tungsten (W), copper (Cu), aluminum (Al), titanium (Ti), tantalum (Ta) or the like, by a sputtering process, an ALD process or a PVD process.

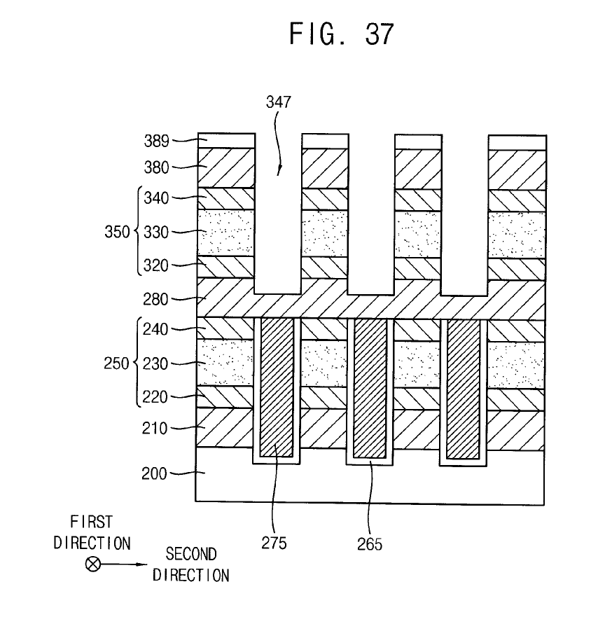

Referring to FIG. 37, a second trench 347 may be formed through the third conductive layer 373, the second upper electrode layer pattern 337, the second variable resistance material layer pattern 327 and the second lower electrode layer pattern 317. In an embodiment according to the inventive concepts, the second trench 347 may extend in the first direction, and a plurality of second trenches 347 may be formed in the second direction.

For example, a third mask 389 extending in the first direction may be formed on the third conductive layer 373 to partially expose a top surface of the third conductive layer 373. The second trench 347 may be formed through the third conductive layer 373, the second upper electrode layer pattern 337, the second variable resistance material layer pattern 327 and the second lower electrode layer pattern 317 by a dry etching process using the third mask 389 as an etching mask. Furthermore, portions of the common insulation layer pattern 365b and the common thermal bather layer pattern 375b may be also removed during the etching process.

In an embodiment according to the inventive concepts, an upper portion of the second conductive line 280 may be also etched when the second trench 346 is formed.

By the formation of the second trench 347, the second lower electrode layer pattern 317, the second variable resistance material layer pattern 327, the second upper electrode layer pattern 337 and the third conductive layer 373 may be transformed into a second lower electrode 320, a second variable resistance layer 330, a second upper electrode 340 and a third conductive line 380, respectively. Accordingly, a second memory cell 350 may be defined by the second lower electrode 320, the second variable resistance layer 330 and the second upper electrode 340. A second variable resistance memory device may be defined by the second conductive line 280, the second memory cell 350 and the third conductive line 380.

Referring to FIG. 30A again, processes similar to those illustrated with reference to FIGS. 6 to 8 may be performed to form a second insulation layer pattern 365a and a second thermal barrier layer pattern 375a in the second trench 347.

In particular, a second insulation layer may be formed on a sidewall and a bottom surface of the second trench 374, and a thermal barrier layer filling a remaining portion of the second trench 374 may be formed on the second insulation layer of, for example, GST, or porous silicon oxide. Upper portions of the second thermal barrier layer and the second insulation layer may be etched by a CMP process and/or an etch-back process until a top surface of the third conductive layer 375 is exposed to form a second thermal barrier layer pattern 375a and a second insulation layer pattern 365a, respectively. The third mask 389 may be removed.

In an embodiment according to the inventive concepts, the second thermal barrier layer pattern 375a and the common thermal barrier layer pattern 375b may cross each other, and may be connected to each other. The common thermal barrier layer pattern 375b and the first thermal barrier layer pattern 275 may also cross each other and may be connected to each other. Thus, the second thermal barrier layer pattern 375a and the first thermal barrier layer pattern 275 may be connected to each other via the common thermal barrier layer pattern 375b.

In an embodiment according to the inventive concepts, the first and second thermal barrier layer patterns 275 and 375a may extend in the first direction, and cross the common thermal barrier layer pattern 375b extending in the second direction to be in communication therewith.

In an embodiment according to the inventive concepts, each first memory cell 250 may be surrounded by the first insulation layer pattern 265, the first thermal barrier layer pattern 275, the common insulation layer pattern 365b and the common thermal barrier layer pattern 375b. Each second memory cell 350 may be surrounded by the second insulation layer pattern 365a, the second thermal barrier layer pattern 375a, the common insulation layer pattern 365b and the common thermal barrier layer pattern 375b.

According to the inventive concepts, each of the first and second thermal barrier layer patterns 275a and 375a and the common thermal barrier layer pattern 375b may be formed to include a material having a thermal conductivity lower than those of the first and second insulation layer patterns 265 and 365a and the common insulation layer pattern 365b. Accordingly, heat transfer between the first and second memory cells 250 and 350 may be decreased because of the first and second thermal barrier layer patterns 275a and 375a and the common thermal barrier layer pattern 375b surrounding the first and second memory cells 250 and 350, and thus an operational reliability of the stacked variable resistance memory device may be improved.

In an example of the present embodiment, an additional variable resistance memory device may be stacked on the second variable memory device. For example, processes illustrated with reference to FIGS. 4 to 13, FIGS. 23 to 27 or FIGS. 31 to 37 may be repeatedly performed to manufacture a stacked variable resistance memory device having a 4-level structure. In this case, an insulating interlayer serving as a base insulation layer for the additional variable resistance memory device may be additionally formed.

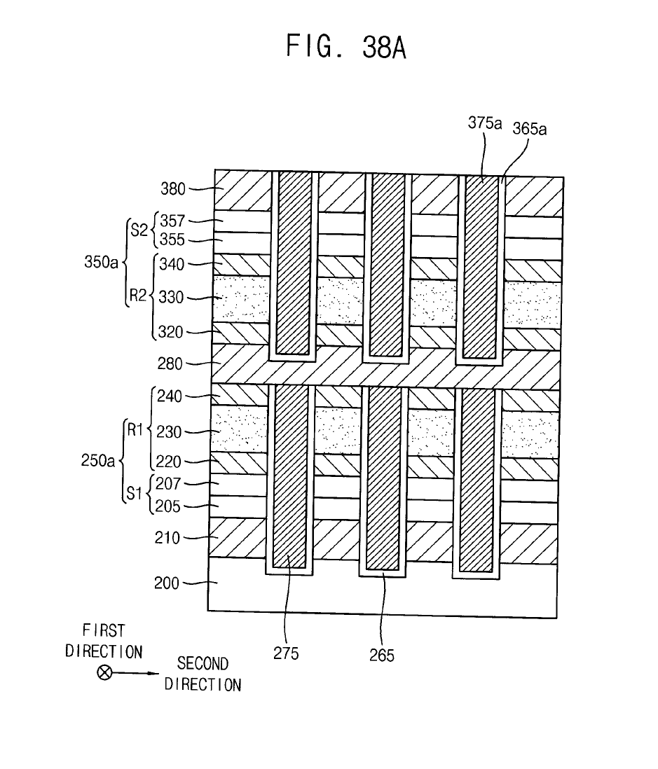

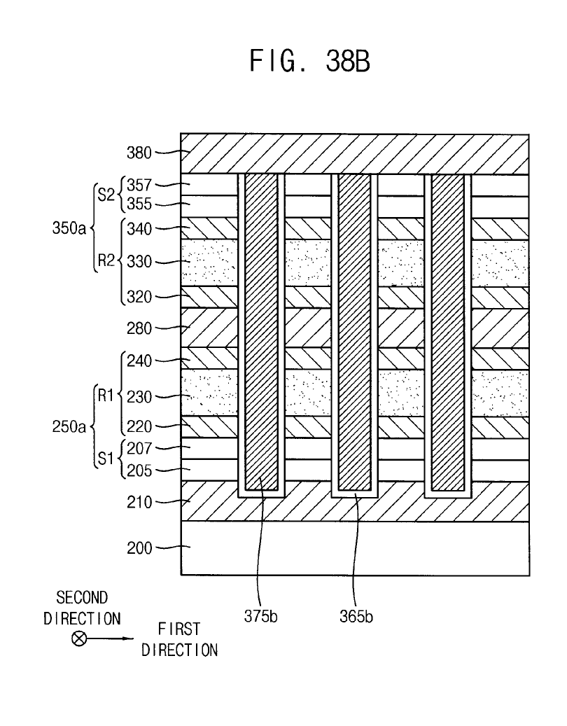

FIGS. 38A and 38B are cross-sectional views illustrating still another embodiment of a stacked variable resistance memory device in accordance with the inventive concepts. Specifically, FIGS. 38A and 38B are cross-sectional views along the second direction and the first direction, respectively.

For example, FIGS. 38A and 38B illustrate a stacked variable resistance memory device having first and second variable memory devices each of which may have a structure in which one selection element and one variable resistance element are formed at each intersection of conductive lines. Each of the first variable resistance memory device and the second variable resistance memory device of the stacked variable resistance memory device may thus be similar to that of FIGS. 30A to 30B except for the inclusion of a first selection element 51 and a second selection element S2. Thus, like reference numerals designate like elements, and repetitive explanations thereon may be omitted herein.

Referring to FIGS. 38A and 38B, the stacked variable resistance memory device may include the first variable resistance memory device, the second variable resistance memory device, and a thermal barrier layer pattern structure on a base insulation layer 200.

The first variable resistance memory device may include a first conductive line 210, a lower portion of a second conductive line 280, a first memory cell 250a, a first thermal barrier layer pattern 275 and a lower portion of a common thermal barrier layer pattern 375b. The second variable resistance memory device may include an upper portion of a second conductive line 280, a second memory cell 350a, a third conductive line 300, a second thermal barrier layer pattern 375a and an upper portion of a common thermal barrier layer pattern 375b.

The first memory cell 250a may include a first selection element 51 and a first variable resistance element R1, which may be formed at an intersection of the first and second conductive lines 210 and 280. The second memory cell 350a may include a selection element S2 and a second variable resistance element R2, which may be formed at an intersection of the second and third conductive lines 280 and 380.

Each of the first and second selection elements S1 and S2 may have a P-N diode structure. In this case, the first selection element S1 may include a first lower semiconductor layer pattern 205 and a first upper semiconductor layer pattern 207 sequentially stacked. The second selection element S2 may include a second upper semiconductor layer pattern 355 and a second lower semiconductor layer pattern 357 sequentially stacked on the second variable resistance element R2. Each of the first and second lower semiconductor layer patterns 205 and 357 may include n-type impurities. Each of the first and second upper semiconductor layer patterns 207 and 355 may include p-type impurities. In an example of the present embodiment, the first selection element S1 may also include a first insulation pattern (not shown) between the first lower semiconductor layer pattern 205 and the first upper semiconductor layer pattern 207, and the second selection element S2 may also include a second insulation pattern (not shown) between the second lower semiconductor layer pattern 357 and the second upper semiconductor layer pattern 355. In this case, each of the first and second selection elements S1 and S2 may have a P-I-N diode structure.

The first variable resistance element R1 may include a first lower electrode 220, a first variable resistance layer 230 and a first upper electrode 240 sequentially stacked on the first selection element S1. The second variable resistance element R2 may include a second upper electrode 320, a second variable resistance layer 330 and a second lower electrode 340 sequentially stacked on the second selection element S2.

The thermal barrier layer pattern structure is formed between the first and second memory cells 250 and 350. In an embodiment according to the inventive concepts, the thermal barrier layer pattern structure may include a first thermal barrier layer pattern 275, a second thermal barrier layer pattern 375a and a common thermal barrier layer pattern 375b.

The first thermal barrier layer pattern 275 may extend through the first variable resistance element R1, the first selection element S1 and the first conductive line 210 adjacent in the second direction. The first thermal barrier layer pattern 275 may Furthermore extend through an upper portion of a base insulation layer 200 so that a lower portion of the first thermal barrier layer pattern 275 may be surrounded by the base insulation layer 200. The second thermal barrier layer pattern 375a may extend between the third conductive line 380, the second variable resistance element R2 and the second selection element S2 adjacent in the second direction. The second thermal barrier layer pattern 375a may further extend through the upper portion of the second conductive line 280 so that a lower portion of the second thermal barrier layer pattern 375a may be surrounded by the second conductive line 280.

The common thermal barrier layer pattern 375b may extend between the first memory cells 250a in the first direction and between the second memory cells 350a adjacent in the first direction. The thermal barrier layer pattern 375b may further extend through an upper portion of the first conductive line 210 so that a lower portion of the thermal barrier layer pattern 375b may be surrounded by the first conductive line 210. Thus, the first and second thermal barrier layer patterns 275 and 375a may be in communication with each other via the common thermal barrier layer pattern 375b.

An insulation layer pattern structure may be formed on sidewalls of the first and second memory cells 250 and 350. In an embodiment according to the inventive concepts, the insulation layer pattern structure may include a first insulation layer pattern 265, a second insulation layer pattern 365a and a common insulation layer pattern 365b.

A sidewall of the first memory cell 250 of the first variable resistance memory device may be surrounded by the first insulation layer pattern 265 extending in the first direction and the lower portion of the common insulation layer pattern 365b extending in the second direction. The first insulation layer pattern 265 and the common insulation layer pattern 365b may be surrounded by the first thermal barrier layer pattern 275 extending in the first direction and the lower portion of the common thermal barrier layer pattern 375b extending in the second direction, respectively. A sidewall of the second memory cell 350a of the second variable resistance memory device may be surrounded by the second insulation layer pattern 365a extending in the first direction and the upper portion of the common insulation layer pattern 365b extending in the second direction. The second insulation layer pattern 365a may be surrounded by the second thermal barrier layer pattern 375a extending in the first direction.

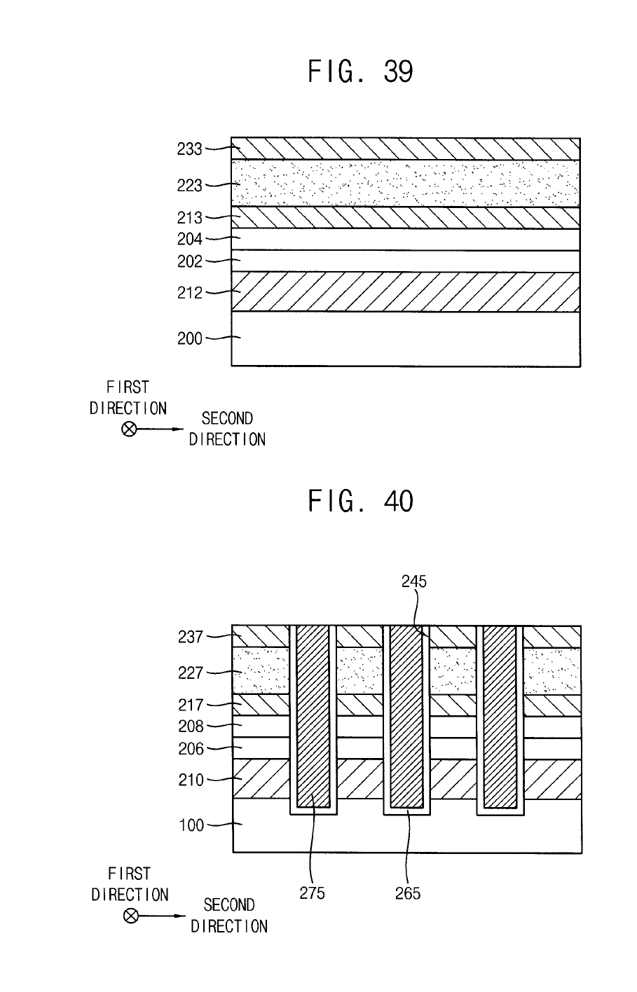

FIGS. 39 to 44B illustrate stages of a method of manufacturing a stacked variable resistance memory device in accordance with the inventive concepts.

The figures may illustrate stages of a method of manufacturing the stacked variable resistance memory device shown in FIGS. 38A and 38B, however, the method is not be limited thereto. This method may include processes similar to those illustrated with reference to FIGS. 31 to 37, and thus like reference numerals designate like elements, and repetitive explanations thereof may be omitted herein.

Referring to FIG. 39, processes similar to those illustrated with reference to FIG. 23 and FIG. 31 may be performed.

Accordingly, a first conductive layer 212, a first lower semiconductor layer 202, a first upper semiconductor layer 204, a first lower electrode layer 213, a first variable resistance material layer 223 and a first upper electrode layer 233 may be sequentially formed on a base insulation layer 200.

Referring to FIG. 40, processes similar to those illustrated with reference to FIGS. 24 and 25, or FIGS. 34 and 35 may be performed.

Accordingly, a first trench 245 may be formed through the first upper electrode layer 233, the first variable resistance material layer 223, the first lower electrode layer 213, the first upper semiconductor layer 204, the first lower semiconductor layer 202 and the first conductive layer 212. A first insulation layer pattern 265 and a first thermal barrier layer pattern 275 extending in the first direction may be formed in the first trench 245.

By the formation of the first trench 245, the first upper electrode layer 233, the first variable resistance material layer 223, the first lower electrode layer 213, the first upper semiconductor layer 204, the first lower semiconductor layer 202 and the first conductive layer 212 may be transformed into a first upper electrode layer pattern 237, a first variable resistance material layer pattern 227, a first lower electrode layer pattern 217, a first upper semiconductor layer line 208, a first lower semiconductor layer line 206 and a first conductive line 210, respectively.

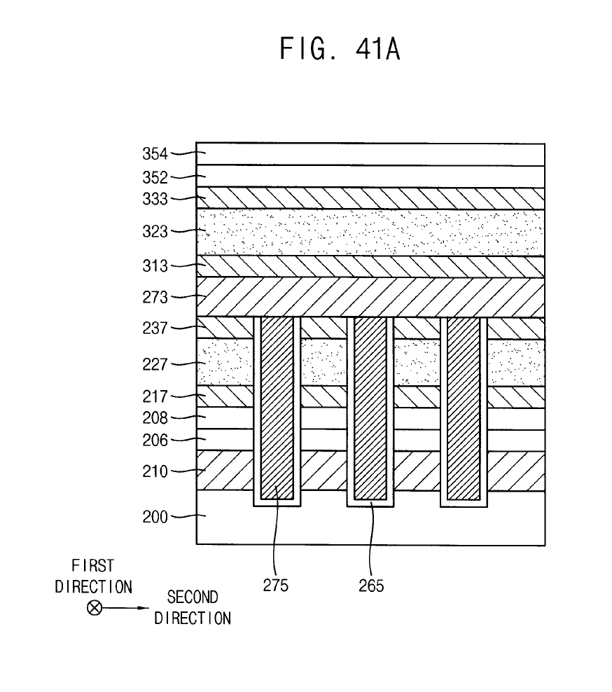

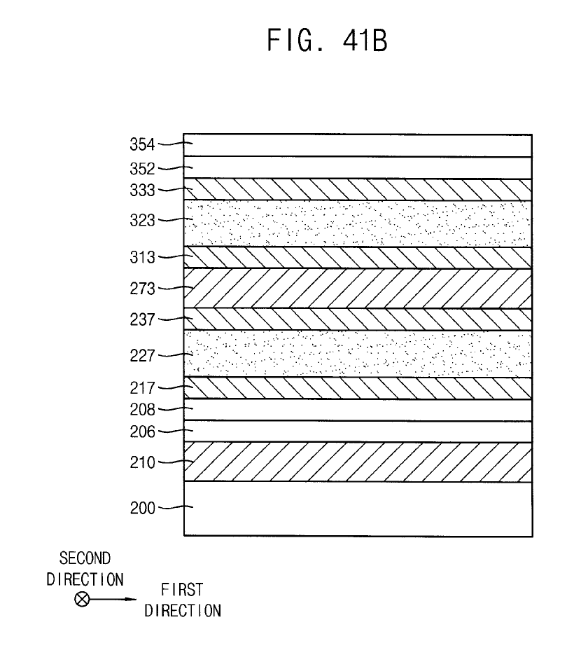

Referring to FIGS. 41A and 41B, a process similar to that illustrated with reference to FIGS. 33A and 33B may be performed.

Accordingly, a second conductive layer 273, a second upper electrode layer 313, a second variable resistance material layer 323, a second lower electrode layer 333, a second upper semiconductor layer 352 and a second lower electrode layer 354 may be sequentially formed on the first upper electrode layer pattern 237, the first insulation layer pattern 265 and the first thermal barrier layer pattern 275.

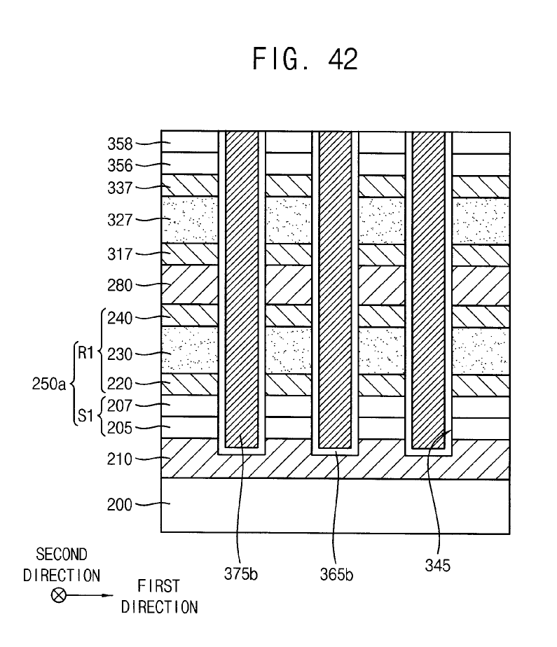

Referring to FIG. 42, processes similar to those illustrated with reference to FIGS. 34 and 35 may be performed.

Accordingly, a common trench 345 extending in the second direction may be formed through the second lower electrode layer 354, the second upper semiconductor layer 352, the second lower electrode layer 333, the second variable resistance material layer 323, the second upper electrode layer 313, the second conductive layer 273, the first upper electrode layer pattern 237, the first variable resistance material layer pattern 227, the first lower electrode layer pattern 217, the first upper semiconductor layer line 208, the first lower semiconductor layer line 206 and an upper portion of the first conductive line 210 in the first direction. A common insulation layer pattern 365b and a common thermal bather layer pattern 375b may be formed in the common trench 345.

By the formation of the common trench 345, the second lower semiconductor layer 354 and the second upper semiconductor layer 352 may be transformed into a second lower semiconductor layer line 358 and a second upper semiconductor layer line 356, respectively. The second lower electrode layer 333, the second variable resistance material layer 323, the second upper electrode layer 313 and the second conductive layer 273 may be transformed into a second lower electrode layer pattern 337, a second variable resistance material layer pattern 327, a second upper electrode layer pattern 317 and a second conductive line 280, respectively.

The first upper electrode layer pattern 237, the first variable resistance material layer pattern 227, the first lower electrode layer pattern 217, the first upper semiconductor layer line 208 and the first lower semiconductor layer line 206 may be transformed into a first upper electrode 240, a first variable resistance layer 230, a first lower electrode 220, a first upper semiconductor layer pattern 207 and a first lower semiconductor layer pattern 205, respectively. Accordingly, a first selection element S1 may be defined by the first lower semiconductor layer pattern 205 and the first upper semiconductor layer pattern 207. A first variable resistance element R1 may be defined by the first lower electrode 220, the first variable resistance layer 230 and the first upper electrode 240. A first memory cell 250a including the first selection element S1 and the first variable resistance element R1 may be formed at each intersection of the first conductive line 210 and the second conductive line 280.

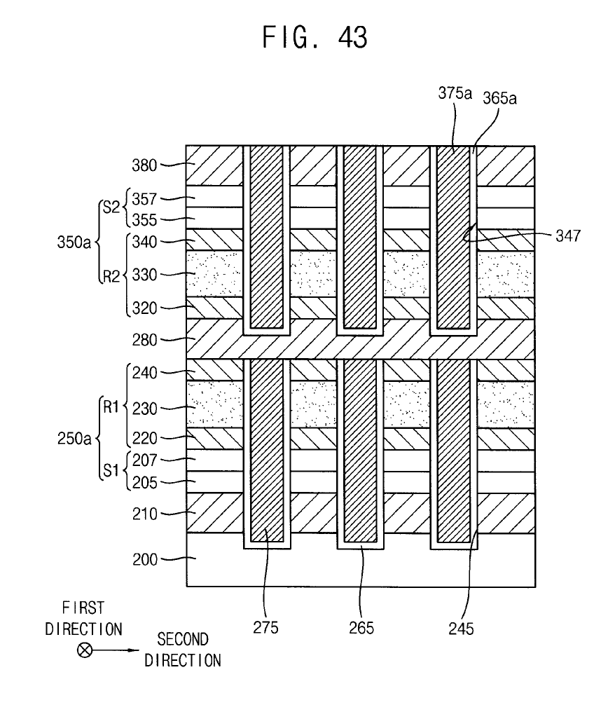

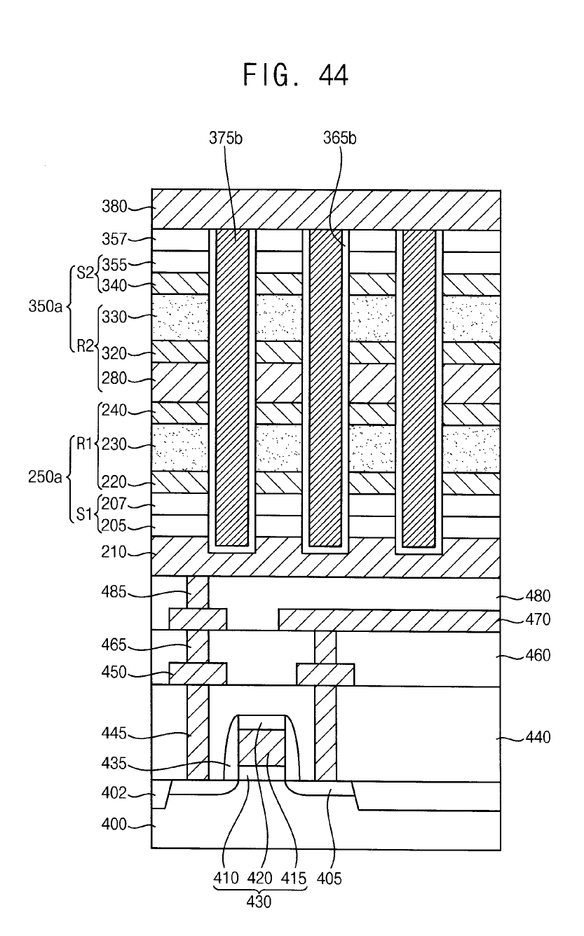

Referring to FIG. 43, processes similar to those illustrated with reference to FIGS. 36A and 37 may be performed.

Accordingly, a third conductive layer may be formed on the second lower semiconductor layer line 358, the common insulation layer pattern 365b and the common thermal barrier layer pattern 375b. A second trench 347 extending in the first direction may be formed through the third conductive layer, the second lower semiconductor layer line 358, the second upper semiconductor layer line 356, the second lower electrode layer pattern 337, the second variable resistance material layer pattern 327, the second upper electrode layer pattern 317 and the second conductive line 280. The upper portion of the second conductive line 280 may be also etched when the second trench 347 is formed. A second insulation layer pattern 365a may be formed on a sidewall and a bottom surface of the second trench 347, and a second thermal barrier layer pattern 375a filling a remaining portion of the second trench 347 may be formed on the second insulation layer pattern 365a.

By the formation of the second trench 347, the third conductive layer, the second lower electrode layer pattern 337, the second variable resistance material layer pattern 327 and the second upper electrode layer pattern 320 may be transformed into a third conductive line 380, a second lower electrode 370, a second variable resistance layer 330 and a second upper electrode 320, respectively. Thus, a second variable resistance element R2 may be defined by the second upper electrode 320, the second variable resistance layer 330 and the second lower electrode 370 sequentially stacked.

Additionally, the second lower semiconductor layer line 358 and the second upper semiconductor layer line 356 may be transformed into a second lower semiconductor layer pattern 357 and a second upper semiconductor layer pattern 355, respectively. Thus, a second selection element S2 may be defined by the second upper semiconductor layer pattern 355 and the second lower semiconductor layer pattern 357.

Accordingly, a second memory cell 350a including the second selection element S2 and the second variable resistance element R2 may be formed at each intersection of the second conductive line 280 and the third conductive line 380.

In an example of the present embodiment, processes illustrated with reference to FIGS. 39 to 43 may be repeatedly performed to manufacture a stacked variable resistance memory device having, for example, a 4-level structure.

FIG. 44 is a cross-sectional view illustrating a semiconductor device in accordance with the inventive concepts. The semiconductor device of FIG. 44 may include a variable resistance memory device stacked on a lower structure including a transistor and wiring.

Referring to FIG. 44, the lower structure may include a gate structure 430, insulating interlayers 440, 460 and 480, contacts 445, 465 and 485, and wirings 450 and 470, which are disposed on a substrate 400.

The substrate 400 may be a semiconductor substrate of, for example, single crystalline silicon or single crystalline germanium. An isolation layer 402 may be formed at an upper portion of the substrate 400 so that the substrate 400 may be divided into an active region and a field region.

The gate structure 430 may include a gate insulation layer pattern 410, a gate electrode 415 and a gate mask 420 sequentially stacked on the substrate 400.

The gate insulation layer pattern 410 may comprise silicon oxide or a metal oxide. The gate electrode 415 may comprise polysilicon doped with impurities, a metal or a metal nitride. The gate mask 420 may comprise silicon nitride. In an example of the present embodiment, a gate spacer 435 may be formed on a sidewall of the gate structure.

An impurity region 405 may be formed at an upper portion of the substrate 400 adjacent to the gate structure 430. For example, the impurity region 405 may include n-type impurities, e.g., phosphorous, arsenic or the like. In this case, a negative metal oxide semiconductor (NMOS) transistor may be defined by the gate structure 430 and the impurity region 405, and a portion of the substrate 400 illustrated in FIG. 44 may be an NMOS region.

In an example of the present embodiment, the substrate 400 may also include a positive metal oxide semiconductor (PMOS) region, and a PMOS transistor including an additional gate structure and a p-type impurity region may be formed on the PMOS region of the substrate 400. Accordingly, a complementary metal oxide semiconductor (CMOS) transistor may be formed on the substrate 400.

In an example of the present embodiment, the gate structure 430 may be at least partially buried or embedded in the substrate 400. In this case, an upper portion of the substrate 400 may be etched to form a recess, and then a gate insulation layer pattern and a gate electrode may be formed in the recess.

A first insulating interlayer 440 covering the gate structure 430, the gate spacer 435 and the impurity region 405 may be formed on the substrate 400. A first contact 445 may extend through the first insulating interlayer 440 to contact the impurity region 405. A first wiring 450 may be disposed on the first insulating interlayer 440 to be electrically connected to the first contact 445.

A second insulating interlayer 460 covering the first wiring 450 may be formed on the first insulating interlayer 440. A second contact 465 may extend through the second insulating interlayer 460 to contact the first wiring 450. A second wiring 470 may be disposed on the second insulating interlayer 460 to be electrically connected to the second contact 465. In an example of the present embodiment, a portion of the second wiring 470 may extend to the PMOS region to be electrically connected to the impurity region of the PMOS transistor.

A third insulating interlayer 480 covering the second wiring 470 may be formed on the second insulating interlayer 460. A third contact 485 may extend through the third insulating interlayer 480 to contact the second wiring 470.

The first to third insulating interlayers 440, 460 and 480 may each comprise silicon oxide, and may serve as the base insulation layer described above. The first to third contacts 445, 465 and 485, the first wiring 450 and the second wiring 470 may comprise a metal, e.g., tungsten (W), aluminum (Al), copper (Cu), titanium (Ti) or the like, and/or a nitride thereof.

A variable resistance memory device in accordance with the inventive concepts may be disposed on the third insulating interlayer 480. A first conductive line 210 of the variable resistance memory device illustrated with reference to FIGS. 38A and 38B may be electrically connected to the third contact 485.

The variable resistance memory device may have a structure in which one selection element and one variable resistance element are formed at each intersection of conductive lines. For example, the variable resistance memory device may be similar to that shown in FIGS. 32A and 32B, FIGS. 29A and 29B or FIGS. 38A and 38B.

Alternatively, the variable resistance memory device may have a structure in which one variable resistance element is formed at each intersection of conductive lines as illustrated in FIGS. 28A and 28B. The variable resistance memory device may be similar to that illustrated with reference to FIGS. 1 to 3B, FIGS. 14 to 15B, or FIGS. 30A and 30B.

FIG. 44 illustrates that the lower structure includes a 2-level wiring structure. However, the lower structure may include a 1-level wiring structure or a multi-level wiring structure having at least 3 levels.

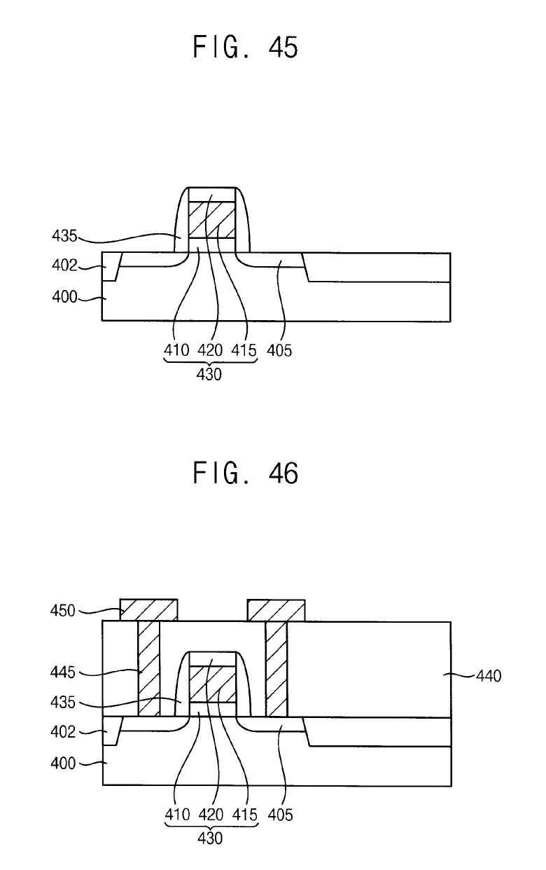

FIGS. 45 to 48 are cross-sectional views illustrating stages of a method of manufacturing a semiconductor device in accordance with the inventive concepts. FIGS. 45 to 48 illustrate a method of manufacturing a semiconductor device of the type shown in FIG. 44, however, the method is not be limited thereto.

Referring to FIG. 45, a gate structure 430 may be formed on a substrate 400, and an impurity region 405 may be formed at an upper portion of the substrate 400 adjacent to the gate structure 430.

The substrate 400 may include an NMOS region and a PMOS region, and a CMOS transistor may be formed on the substrate 400. An isolation layer 402 may be formed at an upper portion of the substrate 400 by, for example, a shallow trench isolation (STI) process. An active region and a field region of the substrate 400 may be defined by the isolation layer 402.

In an embodiment according to the inventive concepts, a gate insulation layer, a gate electrode layer and a gate mask layer may be sequentially formed on the substrate 400, and may be patterned by, for example, a photolithography process to form the gate structure 430 including a gate insulation layer pattern 410, a gate electrode 415 and a gate mask 420.

The gate insulation layer may be formed using silicon oxide by, for example, a CVD process or a thermal oxidation process. The gate electrode layer may be formed using doped polysilicon, a metal or a metal nitride by a sputtering process, an ALD process or the like. The gate mask layer may be formed using silicon nitride by a CVD process, a spin coating process or the like.

An ion implantation process may be performed using the gate structure 430 as an ion implantation mask to form the impurity region 405. In an embodiment according to the inventive concepts, the impurity region 405 may include n-type impurities, e.g., phosphorous, arsenic or the like. In this case, a portion of the substrate 400 illustrated in FIG. 45 may be the NMOS region, and an NMOS transistor may be defined by the impurity region and the gate structure 430. Additionally, a PMOS transistor (not shown) may be formed on the PMOS region of the substrate 400 together with the NMOS transistor.

In an example of the present embodiment, a gate spacer 435 may be formed on a sidewall of the gate structure 430. For example, a spacer layer covering the gate structure 430 may be formed on the substrate 400. The spacer layer may be anisotropically etched to form the gate spacer 435. The gate spacer layer may be formed using silicon nitride by, for example, a CVD process.

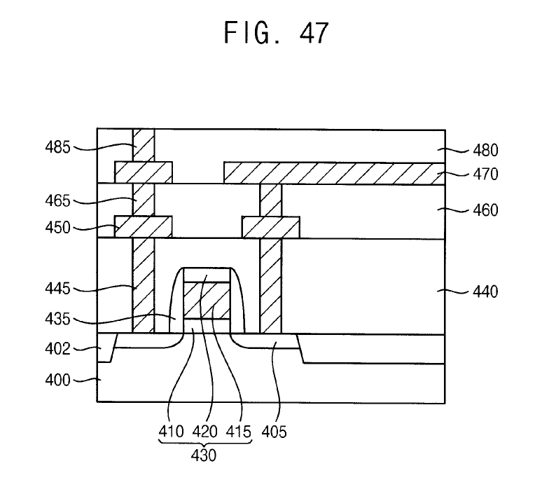

Referring to FIG. 46, a first insulating interlayer 440 covering the gate structure 430 may be formed on the substrate 400. A first contact 445 may be formed through the first insulating interlayer 440 to make contact with the impurity region 405.

For example, the first insulating interlayer 440 may be formed of silicon oxide, e.g., TEOS by, for example, a CVD process or a spin coating process. The first insulating interlayer 440 may be partially removed to form a first contact hole through which the impurity region 405 may be exposed. A first conductive layer sufficiently filling the first contact hole may be formed on the first insulating interlayer 440. An upper portion of the first conductive layer may be planarized until a top surface of the first insulating interlayer 440 may be exposed to form the first contact 445.

In an example of the present embodiment, the first contact 445 may be self-aligned with the gate spacer 435. In this case, the first contact 445 may contact a sidewall of the gate spacer 435.

A first wiring 450 electrically connected to the first contact 445 may be formed on the first insulating interlayer 440. For example, a second conductive layer may be formed on the first insulating interlayer 440 and the first contact 445, and may be patterned to form the first wiring 450. The first and second conductive layers may each be formed of a metal or a metal nitride by an ALD process or a sputtering process.

Referring to FIG. 47, a second insulating interlayer 460 covering the first wiring 450 may be formed on the first insulating interlayer 440. The second insulating interlayer 460 may be partially removed to form a second contact hole through which the first wiring 450 may be at least partially exposed. A third conductive layer sufficiently filling the second contact hole may be formed on the second insulating interlayer 460, and an upper portion of the third conductive layer may be planarized to form a second contact 465 electrically connected to the first wiring 450.

A fourth conductive layer may be formed on the second insulating interlayer 460 and the second contact 465, and may be patterned to form a second 470 wiring electrically connected to the second contact 465. In an embodiment according to the inventive concepts, a plurality of second wirings 470 may be formed, and at least one of the second wirings 470 may extend to the PMOS region to be electrically connected to the PMOS transistor.

A third insulating interlayer 480 covering the second wiring 470 may be formed on the second insulating interlayer 460. A third contact hole may be formed through the third insulating interlayer 480, such that the second wiring 470 may be exposed. A fifth conductive layer filling the third contact hole may be formed on the third insulating interlayer 480, and an upper portion of the fifth conductive layer may be planarized to form a third contact 485 electrically connected to the second wiring 470.

The second and third insulating interlayers 460 and 480 may be formed of insulating material similar to that of the first insulating interlayer 440, e.g., silicon oxide, by a CVD process, a spin coating process or the like. The third to fifth conductive layers may be formed f a metal, e.g., tungsten (W), aluminum (Al), copper (Cu), titanium (Ti) or the like, or a nitride thereof by an ALD process, a sputtering process, a PVD process or the like.

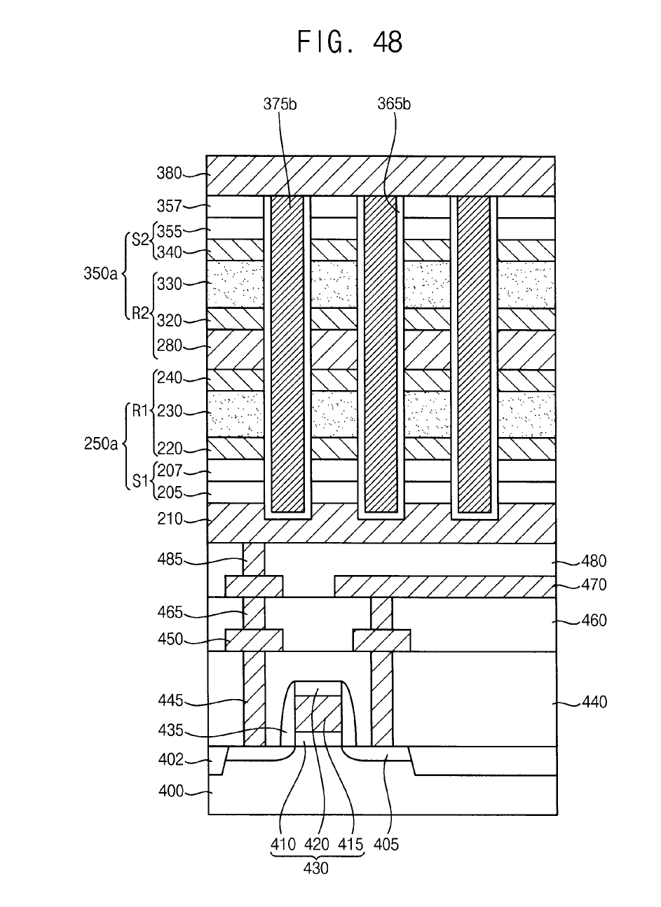

A lower structure including the substrate 400, the transistor, and a wiring structure may be formed by processes illustrated with reference to FIGS. 48 to 50. As illustrated in FIG. 50, the lower structure may have a 2-level wiring structure. However, an additional wiring structure may be stacked in consideration of a circuit design of the semiconductor device.

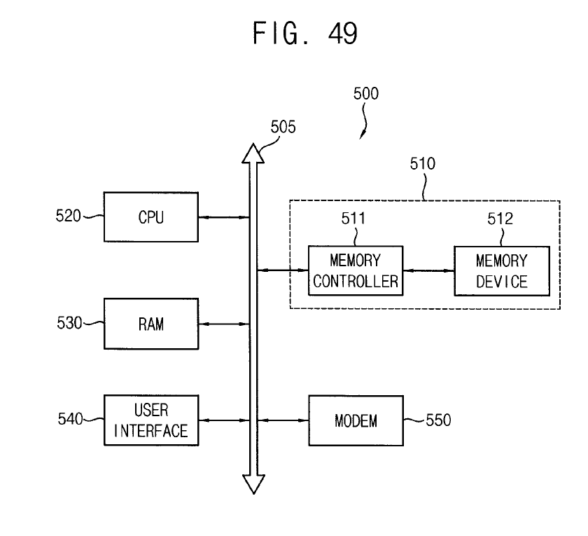

Referring to FIG. 48, a variable resistance memory device may be formed on the lower structure. For example, processes similar to those illustrated with reference to FIGS. 49 to 44 may be performed such that a variable resistance memory device of the type shown in FIGS. 38A and 38B may be formed on the lower structure. In this case, a first conductive line 210 of the variable resistance memory device may be electrically connected to the third contact 485 of the lower structure.

In embodiments according to the inventive concepts, processes similar to those illustrated with reference to FIGS. 4 to 13, FIGS. 16 to 21, FIGS. 23 to 37, FIGS. 31 to 37, or FIGS. 39 to 43 may be performed to form the variable resistance memory device of FIGS. 1 to 3B, FIGS. 14 to 15B, FIGS. 22A and 22B, FIGS. 30A and 30B, or FIGS. 38A and 38B, respectively, on the lower structure. Alternatively, the stacked variable resistance memory device of FIGS. 28A and 28B or FIGS. 29A and 29B may be formed on the lower structure.

FIG. 49 is a block diagram schematically illustrating an information processing system in accordance with the inventive concepts.

Referring to FIG. 49, an information processing system 500 may include a CPU 520, a RAM 530, a user interface 540, a modem 550, e.g., a baseband chipset, and a memory system 510, which may be electrically connected to a system bus 505. The memory system 510 may include a memory device 512 and a memory controller 511. The memory device 512 may include any of the above-described variable resistance memory devices in accordance with the inventive concepts. Thus, large data processed by the CPU 520 or input from an external device may be stored in the memory device 512 with high stability. The memory controller 511 may have a construction capable of controlling the memory device 512. The memory system 510 may serve as a memory card or a solid state disk (SSD) by a combination of the memory device 512 and the memory controller 511. When the information processing system 500 is a mobile device, a battery may be also provided for supplying a driving voltage of the information processing system 500. The information processing system 500 may also include an application chipset, a camera image processor (CIS), a mobile DRAM or the like.

According to the inventive concepts, a variable resistance memory device includes thermal barrier layer patterns on insulation layer patterns surrounding memory cells. The thermal barrier layer patterns are of material having a low thermal conductivity, and heat transfer between the memory cells may be decreased so that an operational reliability of the variable resistance memory device may be improved. The inventive concepts may be applied to various types of non-volatile semiconductor devices, e.g., a ReRAM device, an MRAM device or a PRAM device.

Finally, embodiments of the inventive concept and examples thereof have been described above in detail. The inventive concept may, however, be embodied in many different forms and should not be construed as being limited to the embodiments described above. Rather, these embodiments were described so that this disclosure is thorough and complete, and fully conveys the inventive concept to those skilled in the art. Thus, the true spirit and scope of the inventive concept is not limited by the embodiment and examples described above but by the following claims.

What is claimed is:

1. A variable resistance memory device, comprising:
a plurality of first conductive lines extending in a first direction;
a plurality of second conductive lines disposed over the first conductive lines, the second conductive lines extending in a second direction not parallel to the first direction;
a plurality of memory cells each including a variable resistance element, the memory cells being disposed at locations at which the first and second conductive lines overlap each other, respectively;
a plurality of first insulation layer patterns extending in the first direction between the memory cells;
a plurality of second insulation layer patterns extending in the second direction between the memory cells;
a plurality of first thermal barrier layer patterns extending in the first direction between the first insulation layer patterns, the first thermal barrier layer patterns being separated from the memory cells in the second direction by the first insulation layer patterns; and
a plurality of second thermal barrier layer patterns extending in the second direction between the second insulation layer patterns, the second thermal barrier layer patterns being separated from the memory cells in the first direction by the second insulation layer patterns.

2. The variable resistance memory device of claim 1, wherein the variable resistance element has a variable resistance layer including a perovskite-based material or a transition metal oxide.

3. The variable resistance memory device of claim 1, wherein the plurality of first thermal barrier layer patterns extend in the second direction, and the plurality of second thermal barrier layer patterns extend in the first direction.

4. The variable resistance memory device of claim 1, further comprising:
a third insulation layer pattern on the first thermal barrier layer pattern; and
a fourth insulation layer pattern on the second thermal barrier layer pattern.

5. The variable resistance memory device of claim 1, wherein each of the first and second thermal barrier layer patterns comprises material whose thermal conductivity is lower than those of the first and second insulation layer patterns.

6. The variable resistance memory device of claim 5, wherein the first and second insulation layer patterns comprise silicon oxide, and each of the first and second thermal barrier layer patterns comprise material whose thermal conductivity lower than silicon oxide.

7. The variable resistance memory device of claim 6, wherein the first and second thermal barrier layer patterns comprise at least one material selected from the group consisting of GST, porous silicon oxide and polyimide.

8. The variable resistance memory device of claim 1, wherein the first and second thermal barrier layer patterns intersect each other.

9. The variable resistance memory device of claim 1, wherein each of the memory cells includes a lower electrode, a variable resistance layer and an upper electrode stacked on one of the first conductive lines in the foregoing order.

10. The variable resistance memory device of claim 1, wherein each of the memory cells further includes a selection element interposed between the first conductive line and the variable resistance element.

11. A cross point memory cell array, comprising:
a base;
memory cells disposed on the base and arrayed in first and second directions;
first conductive lines extending parallel to each other in the first direction and interposed between the memory cells and the base;
second conductive lines disposed on the array of memory cells, the second conductive lines extending parallel to each other in the second direction; and
a barrier separating the memory cells from one another,
the barrier comprising an insulation layer pattern structure extending along sidewall surfaces of the memory cells, and a thermal barrier layer pattern structure interposed between adjacent ones of the memory cells in the first and second directions, and
wherein the thermal conductivity of the thermal barrier layer pattern structure is lower than that of the insulation layer pattern structure.

12. The memory cell array of claim 11,
wherein the insulation layer pattern structure comprises first insulation layer patterns extending parallel to each other in the first direction and each of which is interposed between two respective rows of the memory cells adjacent one another in the first direction, and
second insulation layer patterns extending parallel to each other in the second direction and each of which is interposed between two respective columns of the memory cells adjacent one another in the second direction, and
wherein the thermal barrier layer pattern structure comprises first thermal barrier layer patterns extending parallel to each other in the first direction and separated from the rows of memory cells by the first insulation layer patterns, and
second thermal barrier layer patterns extending parallel to each other in the second direction and separated from the columns memory cells by the second insulation layer patterns.

13. The memory cell array of claim 12, wherein the first insulation layer patterns and the first thermal barrier layer patterns extend between the first conductive lines and into the base, and each of the second insulation layer patterns and second thermal barrier layer patterns extends into and terminates within the first conductive layers.

14. The memory cell array of claim 11, wherein each of the memory cells comprises a layer of variable resistance material whose resistance is variable.

15. The memory cell array of claim 11, wherein insulation layer pattern structure comprises silicon oxide, and the thermal barrier layer pattern structure comprises at least one material selected from the group consisting of GST, porous silicon oxide and polyimide.

16. A method of manufacturing a variable resistance memory device, comprising:
forming a first conductive layer and a first variable resistance material layer on a base insulation layer;
etching the first variable resistance material layer and the first conductive layer to form a plurality of first trenches extending in a first direction;
forming a first insulation layer pattern along sides of each of the first trenches, and subsequently forming a first thermal barrier layer pattern over the first insulation layer pattern in the first trenches;
forming a second conductive layer on the first variable resistance material layer, the first insulation layer pattern and the first thermal barrier layer pattern;
etching the first conductive layer, the first variable resistance material layer and the second conductive layer to form a plurality of second trenches extending in a second direction not parallel to the first direction; and
forming a second insulation layer pattern along sides of each of the second trenches, and subsequently forming a second thermal barrier layer pattern over the second insulation layer pattern in the second trenches.

17. The method of claim 16, further comprising:
forming a second variable resistance material layer on the second conductive layer; and
wherein the second variable resistance material layer is etched along with the second conductive layer, the first variable resistance material layer and the first conductive layer to form the second trenches extending in the second direction.

18. The method of claim 17, further comprising:
forming a third conductive layer on the second variable resistance material layer, the second insulation layer pattern and the second thermal barrier layer pattern;
etching the third conductive layer and the second variable resistance material layer to form a plurality of third trenches extending in the first direction; and
forming a plurality of third insulation layer patterns along sides of each of the third trenches, and subsequently forming a plurality of third thermal barrier layers over the third insulation layer patterns.

19. The method of claim 18, wherein the first and third thermal barrier layer patterns are connected to each other via the second thermal barrier layer pattern.

20. The method of claim 11, wherein each of the first and second thermal barrier layer patterns is formed of material whose thermal conductivity is lower than those of the first and second insulation layer patterns.
